(19) United States
(12) Patent Application Publication
(10) Pub. No.: US 2023/0065016 A1
(43) Pub. Date: Mar. 2, 2023

(54) DISPLAY DEVICE AND METHOD FOR FABRICATING THE SAME

(71) Applicant: Samsung Display Co., LTD., Yongin-si (KR)

(72) Inventors: Jin Woo CHOI, Seoul (KR); Min Woo KIM, Hwaseong-si (KR); Sung Kook PARK, Suwon-si (KR); Sung Eun BAEK, Suwon-si (KR); Ki Seong SEO, Seoul (KR); Hyung Il JEON, Seoul (KR)

(73) Assignee: Samsung Display Co., LTD., Yongin-si (KR)

(21) Appl. No.: 17/752,289

(22) Filed: May 24, 2022

(30) Foreign Application Priority Data
Aug. 26, 2021 (KR) 10-2021-0113121

(51) Int. Cl. H01L 25/16; H01L 23/00; H01L 33/00

(52) U.S. Cl. CPC H01L 25/167; H01L 24/24; H01L 24/32; H01L 24/33; H01L 24/83; H01L 24/82; H01L 24/25; H01L 24/05; H01L 24/08; H01L 24/09; H01L 33/0093; H01L 33/0095; H01L 24/80; H01L 33/24

(57) ABSTRACT

A display includes a pixel electrode disposed on a substrate, a light emitting element disposed on the pixel electrode, a connection electrode disposed on a side surface of the light emitting element, and a common electrode disposed on the light emitting element. The light emitting element includes a first sub light emitting element, a second sub light emitting element disposed on the first sub light emitting element, and a third sub light emitting element disposed on the second sub light emitting element. The connection electrode is disposed on at least one side surface of the first sub light emitting element, the second sub light emitting element, and the third sub light emitting element.

### CROSS-REFERENCE TO RELATED APPLICATION(S)

This application claims priority to and benefits of Korean Patent Application No. 10-2021-0113121 filed in the Korean Intellectual Property Office (KIPO) on Aug. 26, 2021, under 35 U.S.C. § 119, the entire contents of which are incorporated herein by reference.

### BACKGROUND

### 1. Technical Field

The disclosure relates to a display device and a method for fabricating the same.

### 2. Description of the Related Art

With the advance of information-oriented society, more and more demands are placed on display devices for displaying images in various ways. The display device may be a flat panel display device such as a liquid crystal display, a field emission display and a light emitting display. The light emitting display device may include an organic light emitting display device including an organic light emitting diode element as a light emitting element, an inorganic light emitting display device including an inorganic semiconductor element as a light emitting element, or a micro light emitting display device including a micro light emitting diode element as a light emitting element.

Recently, a head mounted display including a light emitting display device has been developed. A head mounted display (HIVID) is a glasses-type monitor device of virtual reality (VR) or augmented reality that is worn in the form of glasses or a helmet to form a focus at a distance close to the user's eyes.

A high-resolution ultra-small light emitting diode display panel including a micro light emitting diode element is applied to the head mounted display. In case that the ultra-small light emitting diode element emits light of a single color, in order for the ultra-small light emitting diode display panel to display various colors, a wavelength conversion layer for converting the wavelength of light emitted from the ultra-small light emitting diode element is essential. However, in case that a high-resolution ultra-small light emitting diode display panel includes a wavelength conversion layer, a partition wall (or bank) having a high aspect ratio is required to partition the wavelength conversion layer, and it is not easy to fabricate the partition wall having a high aspect ratio.

### SUMMARY

Embodiments may provide a display device that does not require a wavelength conversion layer and a partition wall (or bank) by including an ultra-small light emitting diode element emitting red light, an ultra-small light emitting diode element emitting green light, and an ultra-small light emitting diode element emitting blue light, and a method for fabricating the same.

Additional features of embodiments will be set forth in the description which follows, and in part may be apparent from the description, or may be learned by practice of an embodiment or embodiments herein.

According to an embodiment, a display includes a pixel electrode disposed on a substrate, a light emitting element disposed on the pixel electrode, a connection electrode disposed on a side surface of the light emitting element, and a common electrode disposed on the light emitting element. The light emitting element includes a first sub light emitting element, a second sub light emitting element disposed on the first sub light emitting element, and a third sub light emitting element disposed on the second sub light emitting element. The connection electrode is disposed on at least one side surface of the first sub light emitting element, the second sub light emitting element, and the third sub light emitting element.

Each of the first sub light emitting element, the second sub light emitting element, and the third sub light emitting element may include a first semiconductor layer, an active layer, and a second semiconductor layer sequentially stacked.

The connection electrode may be disposed on a side surface of the second semiconductor layer of the first sub light emitting element, a side surface of the first semiconductor layer, a side surface of the active layer, and a side surface of the second semiconductor layer of the second sub light emitting element, and a side surface of the first semiconductor layer, a side surface of the active layer, and a side surface of the second semiconductor layer of the third sub light emitting element.

The connection electrode may be electrically connected to the common electrode.

The first sub light emitting element may emit light of a first color wavelength band.

The connection electrode may include a first sub connection electrode disposed on a side surface of the first semiconductor layer, a side surface of the active layer, and a side surface of the second semiconductor layer of the first sub light emitting element, and a side surface of the first semiconductor layer of the second sub light emitting element, and a second sub connection electrode disposed on a side surface of the active layer of the second sub light emitting element and a side surface of the first semiconductor layer, a side surface of the active layer, and a side surface of the second semiconductor layer of the third sub light emitting element.

The second sub connection electrode may be electrically connected to the common electrode.

The second sub light emitting element may emit light of a second color wavelength band.

The connection electrode may be disposed on a side surface of the first semiconductor layer, a side surface of the active layer, and a side surface of the second semiconductor layer of the first sub light emitting element, and a side surface of the first semiconductor layer, a side surface of the active layer, and a side surface of the second semiconductor layer of the second sub light emitting element, and a side surface of the first semiconductor layer of the third sub light emitting element.

The connection electrode may be spaced apart from the common electrode.

The third sub light emitting element may emit light of a third color wavelength band.

The display device may further include a first adhesive layer disposed between the first sub light emitting element and the second sub light emitting element, and a second adhesive layer disposed between the second sub light emitting element and the third sub light emitting element.

Each of a thickness of the first adhesive layer and a thickness of the second adhesive layer may be smaller than a thickness of the connection electrode.

The first adhesive layer, the second adhesive layer, and the connection electrode may include the same material.

According to an embodiment, a display device includes a first pixel electrode and a second pixel electrode disposed on a substrate and spaced apart from each other, a first light emitting element disposed on the first pixel electrode, a second light emitting element disposed on the second pixel electrode, a first connection electrode disposed on at least a portion of a side surface of the first light emitting element, a second connection electrode disposed on at least a portion of a side surface of the second light emitting element, and a common electrode disposed on the first light emitting element and the second light emitting element. The common electrode is electrically connected to at least one of the first connection electrode and the second connection electrode.

The display device may further include a third pixel electrode disposed on the substrate and spaced apart from the first pixel electrode and the second pixel electrode, a third light emitting element disposed on the third pixel electrode, and a third connection electrode disposed on at least a portion of a side surface of the third light emitting element. The common electrode is electrically connected to at least two of the first connection electrode, the second connection electrode, and the third connection electrode.

Each of the first light emitting element, the second light emitting element, and the third light emitting element may include a first sub light emitting element, a second sub light emitting element disposed on the first sub light emitting element, and a third sub light emitting element disposed on the second sub light emitting element. Each of the first sub light emitting element, the second sub light emitting element, and the third sub light emitting element may include a first semiconductor layer, an active layer, and a second semiconductor layer sequentially stacked.

The first connection electrode may be electrically connected to the second semiconductor layer of the first sub light emitting element, the first semiconductor layer, the active layer, and the second semiconductor layer of the second sub light emitting element, and the first semiconductor layer, the active layer, and the second semiconductor layer of the third sub light emitting element of the first light emitting element.

The second connection electrode may include a first sub connection electrode electrically connected to the first semiconductor layer, the active layer, and the second semiconductor layer of the first sub light emitting element and the first semiconductor layer of the second sub light emitting element of the second light emitting element, and a second sub connection electrode electrically connected to the second semiconductor layer of the second sub light emitting element, and the first semiconductor layer, the active layer, and the second semiconductor layer of the third sub light emitting element of the second light emitting element.

The third connection electrode may be electrically connected to the first semiconductor layer, the active layer, and the second semiconductor layer of the first sub light emitting element, the first semiconductor layer, the active layer, and the second semiconductor layer of the second sub light emitting element, and the first semiconductor layer of the third sub light emitting element of the third light emitting element.

According to an embodiment, a method for fabricating a display device, includes adhering a pixel electrode disposed on a substrate to a first light emitting element layer disposed on a first light emitting element substrate by bonding electrode layers, adhering a first sub adhesive layer disposed on the first light emitting element layer to a second sub adhesive layer disposed on the second light emitting element layer, adhering a third sub adhesive layer disposed on the second light emitting element layer to a fourth sub adhesive layer disposed on the third light emitting element layer, forming a first mask pattern on the third light emitting element layer, and etching the first light emitting element layer, the second light emitting element layer, and the third light emitting element layer exposed without being covered by the first mask pattern to form first light emitting elements, second light emitting elements, and third light emitting elements, removing the first mask pattern, and forming a connection electrode layer on the first light emitting elements, the second light emitting elements, and the third light emitting elements, and forming a second mask pattern on the connection electrode layer, and etching the connection electrode layer exposed without being covered by the second mask pattern to form a first connection electrode, a second connection electrode, and a third connection electrode.

According to an embodiment, by including a first light emitting element emitting a first light, a second light emitting element emitting a second light, and a third light emitting element emitting a third light, it is possible to display various colors without a wavelength conversion layer, and moreover, there is no need for a partition wall to partition the wavelength conversion layer.

Other features and embodiments may be apparent from the following detailed description, the drawings, and the claims.

### BRIEF DESCRIPTION OF THE DRAWINGS

The accompanying drawings, which are included to provide a further understanding of the disclosure, illustrate embodiments in which:

FIG. 1 is a schematic perspective view illustrating a display device according to an embodiment;

FIG. 2 is a schematic layout view illustrating area A of FIG. 1 in detail;

FIG. 3 is a schematic layout view illustrating pixels of a display panel according to an embodiment;

FIG. 4 is a graph showing an example of a main peak wavelength of a first light, a main peak wavelength of a second light, and a main peak wavelength of a third light;

FIG. 5 is a schematic cross-sectional view illustrating an example of a display panel taken along line A-A′ of FIG. 2;

FIG. 6 is a schematic enlarged cross-sectional view showing an example of a first light emitting element of FIG. 5 in detail;

FIG. 7 is a schematic enlarged cross-sectional view showing an example of a second light emitting element of FIG. 5 in detail;

FIG. 8 is a schematic enlarged cross-sectional view showing an example of a third light emitting element of FIG. 5 in detail;

FIG. 9A is a schematic cross-sectional view illustrating an example of a display panel taken along line A-A′ of FIG. 3;

FIG. 9B is a schematic cross-sectional view illustrating another example of a display panel taken along line A-A′ of FIG. 3;

FIG. 9C is a schematic cross-sectional view illustrating an example of a display panel taken along line A-A′ of FIG. 3;

FIG. 10 is a schematic layout view illustrating pixels of a display panel according to still another embodiment;

FIG. 11 is a schematic layout view illustrating pixels of a display panel according to still another embodiment;

FIG. 12 is a schematic cross-sectional view illustrating an example of a display panel taken along line B-B′ of FIG. 11;

FIG. 13 is a schematic layout view illustrating another example of area A of FIG. 1 in detail;

FIG. 14 is a schematic layout view illustrating pixels of a display panel according to still another embodiment;

FIG. 15 is schematic a cross-sectional view illustrating an example of a display panel taken along line C-C′ of FIG. 14;

FIG. 16 is a schematic cross-sectional view illustrating an example of a display panel taken along line D-D′ of FIG. 14;

FIG. 17 is a schematic layout view illustrating pixels of a display panel according to still another embodiment;

FIG. 18 is a schematic cross-sectional view illustrating an example of a display panel taken along line E-E′ of FIG. 17;

FIG. 19 is a schematic cross-sectional view illustrating an example of a display panel taken along line F-F′ of FIG. 17;

FIG. 20 is a schematic flowchart illustrating a method for fabricating a display panel according to an embodiment;

FIGS. 21 to 28 are schematic cross-sectional views illustrating a method for fabricating a display panel according to an embodiment;

FIG. 29 is a schematic diagram illustrating an example virtual reality device including a display device according to an embodiment;

FIG. 30 is a schematic diagram illustrating an example smart device including a display device according to an embodiment;

FIG. 31 is a schematic diagram illustrating an example vehicle instrument panel and a center fascia including a display device according to an embodiment;

FIG. 32 is a schematic diagram illustrating an example transparent display device including a display device according to an embodiment; and

FIG. 33 is a schematic diagram of an equivalent circuit of a pixel circuit unit and a light emitting element according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

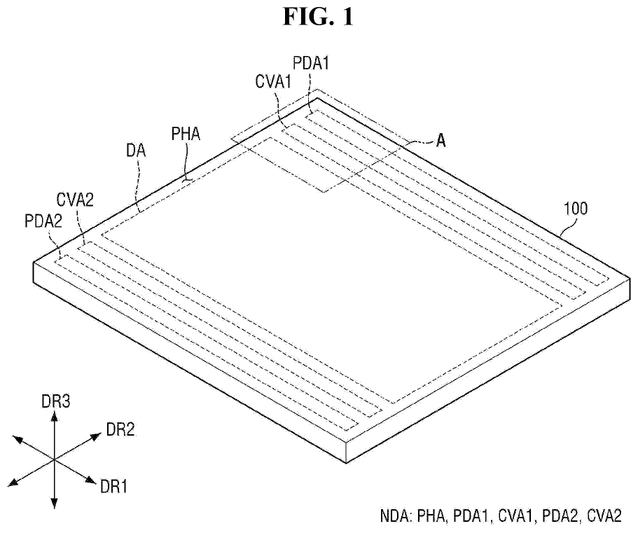

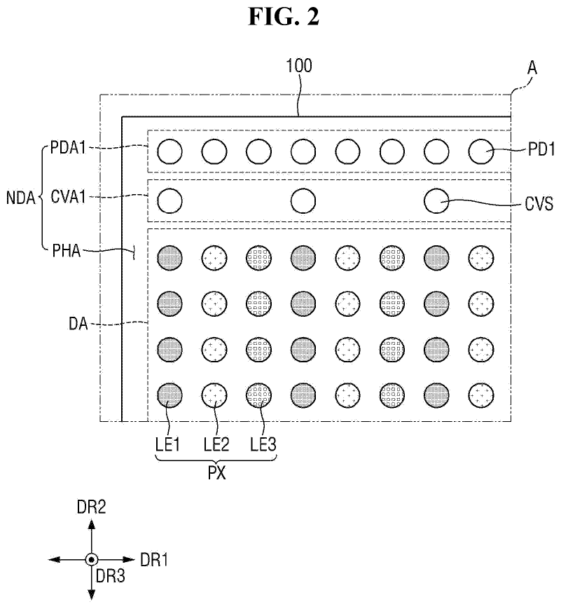

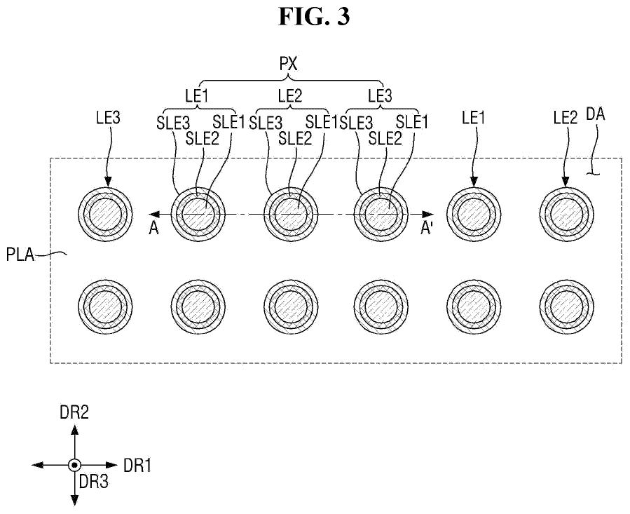

FIG. 1 is a schematic layout view illustrating a display device according to an embodiment. FIG. 2 is a schematic layout view illustrating area A of FIG. 1 in detail. FIG. 3 is a schematic layout view illustrating pixels of a display panel according to an embodiment.

As illustrated in FIGS. 1 to 3, the display device according to an embodiment is described as being an ultra-small light emitting diode display device (micro or nano light emitting diode display device) including an ultra-small light emitting diode (micro or nano light emitting diode) as a light emitting element, but the embodiment of the specification is not limited thereto.

In addition, as illustrated in FIGS. 1 to 3, the display device according to an embodiment is described as being a light emitting diode on silicon (LEDoS) in which light emitting diodes are disposed as light emitting elements on a semiconductor circuit substrate 110 formed by a semiconductor process using a silicon wafer, but it should be noted that the embodiment of the specification is not limited thereto.

In addition, as illustrated in FIGS. 1 to 3, a first direction DR1 indicates a horizontal direction of a display panel 100, a second direction DR2 indicates a vertical direction of the display panel 100, and a third direction DR3 indicates a thickness direction of the display panel 100 or a thickness direction of the semiconductor circuit substrate 110. In this case, “left”, “right”, “upper”, and “lower” indicate directions when the display panel 100 is viewed from above. For example, “right side” indicates a side in the first direction DR1, “left side” indicates the other side in the first direction DR1, “upper side” indicates a side in the second direction DR2, and “lower side” indicates the other side in the second direction DR2. In addition, “upper portion” refers to a side in the third direction DR3, and “lower portion” refers to the other side in the third direction DR3.

Referring to FIGS. 1 to 3, a display device 10 according to an embodiment includes the display panel 100 including a display area DA and a non-display area NDA.

The display panel 100 may have a quadrilateral planar shape having long sides in the first direction DR1 and short sides in the second direction DR2. However, the planar shape of the display panel 100 is not limited thereto, and may have a polygonal shape other than a quadrilateral shape, a circular shape, an elliptical shape, or an irregular planar shape.

The display area DA may be an area in which an image is displayed, and the non-display area NDA may be an area in which an image is not displayed. The planar shape of the display area DA may follow the planar shape of the display panel 100. FIG. 1 illustrates that the planar shape of the display area DA is a quadrilateral shape. The display area DA may be disposed in a central area of the display panel 100. The non-display area NDA may be disposed around the display area DA. The non-display area NDA may be disposed to surround the display area DA.

The display area DA of the display panel 100 may include pixels PX. The pixel PX may be defined as a minimum light emitting part capable of displaying white light.

Each of the pixels PX may include first to third light emitting elements LE1, LE2, and LE3 emitting light. In the embodiment of the specification, it is described that each of the pixels PX includes three light emitting elements LE1, LE2, and LE3, but the embodiment of the specification is not limited thereto. In addition, it is exemplified that each of the first to third light emitting elements LE1, LE2, and LE3 has a circular planar shape, but the embodiment of the specification is not limited thereto.

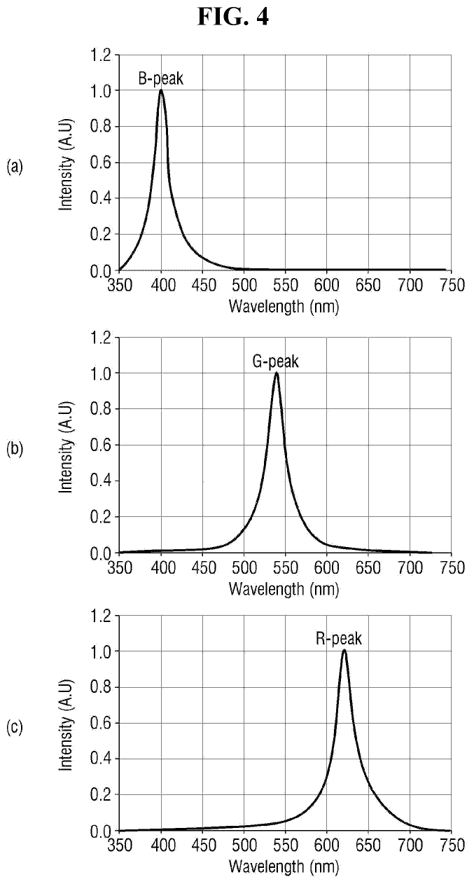

The first light emitting element LE1 may emit a first light. The first light may be light of a red wavelength band. For example, the main peak wavelength (R-peak) of the first light may be positioned at approximately 600 nm to approximately 750 nm as illustrated in (c) of FIG. 4, but the embodiment of the specification is not limited thereto.

The second light emitting element LE2 may emit a second light. The second light may be light of a green wavelength band. For example, the main peak wavelength (G-peak) of the second light may be positioned in approximately 480 nm to approximately 560 nm as illustrated in (b) of FIG. 4, but the embodiment of the specification is not limited thereto.

The third light emitting element LE3 may emit a third light. The third light may be light of a blue wavelength band. For example, the main peak wavelength (B-peak) of the third light may be positioned in approximately 370 nm to approximately 460 nm as illustrated in (a) of FIG. 4, but the embodiment of the specification is not limited thereto.

The first light emitting elements LE1, the second light emitting elements LE2, and the third light emitting elements LE3 may be alternately arranged in the first direction DR1. For example, the first light emitting elements LE1, the second light emitting elements LE2, and the third light emitting elements LE3 may be disposed in the order of the first light emitting element LE1, the second light emitting element LE2, and the third light emitting element LE3 in the first direction DR1.

The first light emitting elements LE1 may be arranged in the second direction DR2. The second light emitting elements LE2 may be arranged in the second direction DR2. The third light emitting elements LE3 may be arranged in the second direction DR2.

A planarization layer PLA may expose, without covering (or overlapping in a plan view), the top surface of each of the first light emitting elements LE1, the second light emitting elements LE2, and the third light emitting elements LE3. FIG. 3 illustrates that the top surface of each of the first light emitting elements LE1, the second light emitting elements LE2, and the third light emitting elements LE3 exposed without being covered by the planarization layer PLA has a circular planar shape, but the embodiment of the specification is not limited thereto. In addition, the planarization layer PLA may be disposed to cover the side surface of each of the first light emitting elements LE1, the second light emitting elements LE2, and the third light emitting elements LE3.

The non-display area NDA may include a first common voltage supply area CVA1, a second common voltage supply area CVA2, a first pad portion PDA1, a second pad portion PDA2, and a peripheral area PHA.

The first common voltage supply area CVA1 may be disposed between the first pad portion PDA1 and the display area DA. The second common voltage supply area CVA2 may be disposed between the second pad portion PDA2 and the display area DA. Each of the first common voltage supply area CVA1 and the second common voltage supply area CVA2 may include common voltage supply parts CVS electrically connected to a common electrode CE. A common voltage may be supplied to the common electrode CE through the common voltage supply parts CVS.

The common voltage supply parts CVS of the first common voltage supply area CVA1 may be electrically connected to one of the first pads PD1 of the first pad portion PDA1. For example, the common voltage supply parts CVS of the first common voltage supply area CVA1 may be supplied with a common voltage from one of the first pads PD1 of the first pad portion PDA.

The common voltage supply parts CVS of the second common voltage supply area CVA2 may be electrically connected to one of the second pads of the second pad portion PDA2. For example, the common voltage supply parts CVS of the second common voltage supply area CVA2 may be supplied with a common voltage from one of the second pads of the second pad portion PDA2.

The first pad portion PDA1 may be disposed on the upper side of the display panel 100. The first pad portion PDA1 may include first pads PD1 electrically connected to an external circuit board.

The second pad portion PDA2 may be disposed on the lower side of the display panel 100. The second pad portion PDA2 may include second pads electrically connected to an external circuit board. The second pad portion PDA2 may be omitted.

The peripheral area PHA may be an area in the non-display area NDA, excluding the first common voltage supply area CVA1, the second common voltage supply area CVA2, the first pad portion PDA1, and the second pad portion PDA2. The peripheral area PHA may be disposed to surround not only the display area DA, but also the first common voltage supply area CVA1, the second common voltage supply area CVA2, the first pad portion PDA1, and the second pad portion PDA2.

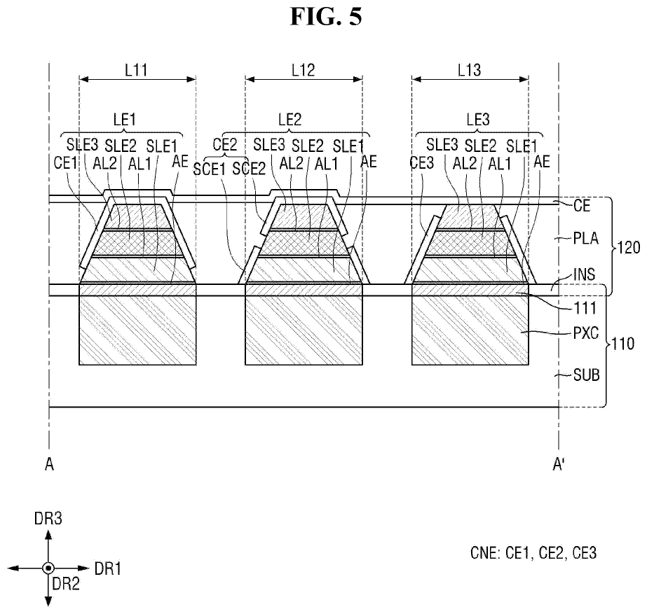

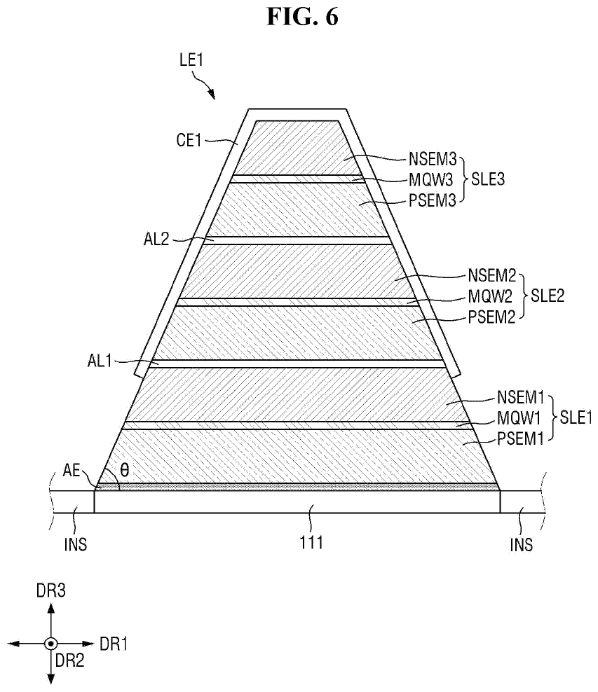

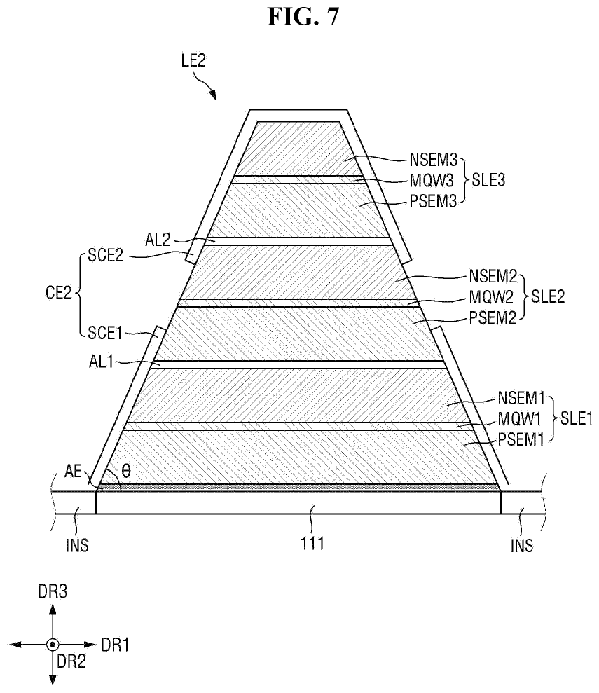

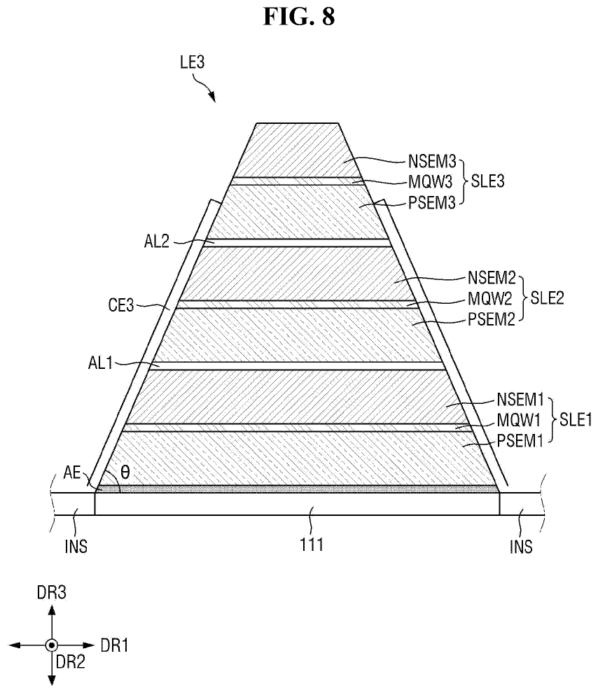

FIG. 5 is a schematic cross-sectional view illustrating an example of a display panel taken along line A-A′ of FIG. 3. FIG. 6 is a schematic enlarged cross-sectional view illustrating an example of a first light emitting element of FIG. 5 in detail. FIG. 7 is a schematic enlarged cross-sectional view illustrating an example of a second light emitting element of FIG. 5 in detail. FIG. 8 is a schematic enlarged cross-sectional view illustrating an example of a third light emitting element of FIG. 5 in detail.

Referring to FIGS. 5 to 8, the display panel 100 may include the semiconductor circuit substrate 110 and a light emitting element layer 120. The semiconductor circuit substrate 110 may include a substrate SUB, pixel circuit parts PXCs, and pixel electrodes 111.

The substrate SUB may be a silicon wafer substrate. The substrate SUB may be made of monocrystalline silicon.

Each of the pixel circuit parts PXC may be disposed on the substrate SUB. Each of the pixel circuit parts PXC may include a complementary metal-oxide semiconductor (CMOS) circuit formed using a semiconductor process. As another example, each of the pixel circuit parts PXC may include a thin-film transistor circuit formed using a thin-film transistor process.

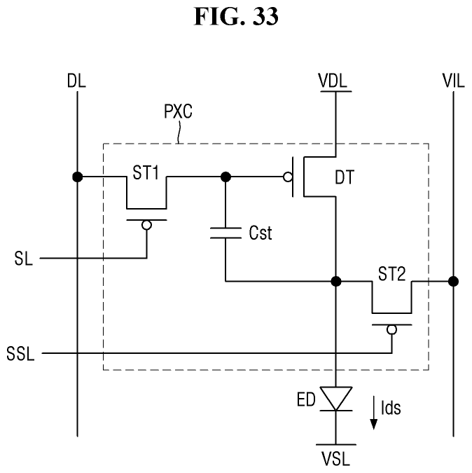

Each of the pixel circuit parts PXC may include at least one transistor. In addition, each of the pixel circuit parts PXC may further include at least one capacitor. For example, each of the pixel circuit parts PXC may include a driving transistor DT, a first transistor ST1, a second transistor ST2, and a capacitor Cst as illustrated in FIG. 33.

A light emitting element LE emits light according to a driving current Ids (see, e.g., FIG. 33). The amount of light emitted from the light emitting element LE may be proportional to the driving current Ids. The anode electrode of the light emitting element LE may be electrically connected to the source electrode of the driving transistor DT, and the cathode electrode thereof may be electrically connected to a second power supply line VSL to which a low-potential voltage lower than a high-potential voltage is supplied.

The driving transistor DT adjusts a current flowing from a first power supply line VDL, to which a first power supply voltage is supplied, to the light emitting element LE according to a voltage difference between the gate electrode and the source electrode of the driving transistor DT. The gate electrode of the driving transistor DT may be electrically connected to the first electrode of the first transistor ST1, the source electrode thereof may be electrically connected to the anode electrode of the light emitting element LE, and the drain electrode thereof may be electrically connected to the first power supply line VDL to which a high-potential voltage is applied.

The first transistor ST1 is turned on by a scan signal from a scan line SL to electrically connect a data line DL to the gate electrode of the driving transistor DT. The gate electrode of the first transistor ST1 may be electrically connected to the scan line SL, the first electrode thereof may be electrically connected to the gate electrode of the driving transistor DT, and the second electrode thereof may be electrically connected to the data line DL.

The second transistor ST2 is turned on by a sensing signal from a sensing signal line SSL to electrically connect an initialization voltage line VIL to the source electrode of the driving transistor DT. The gate electrode of the second transistor ST2 may be electrically connected to the sensing signal line SSL, the first electrode thereof may be electrically connected to the initialization voltage line VIL, and the second electrode thereof may be electrically connected to the source electrode of the driving transistor DT.

The first electrode of each of the first and second transistors ST1 and ST2 may be a source electrode, and the second electrode thereof may be a drain electrode, but it should be noted that the disclosure is not limited thereto. For example, the first electrode of each of the first and second transistors ST1 and ST2 may be a drain electrode, and the second electrode thereof may be a source electrode.

The capacitor Cst is formed between the gate electrode and the source electrode of the driving transistor DT. The capacitor Cst stores a voltage corresponding to a difference between the gate voltage and the source voltage of the driving transistor DT.

As illustrated in FIG. 33, the driving transistor DT and the first and second transistors ST1 and ST2 are described as being formed as an n-type metal-oxide-semiconductor field-effect transistor (MOSFET), but it should be noted that the disclosure is not limited thereto. The driving transistor DT and the first and second transistors ST1 and ST2 may be formed of a p-type MOSFET.

The pixel circuit parts PXC may be disposed in the display area DA. Each of the pixel circuit parts PXC may be electrically connected to the corresponding pixel electrode 111. For example, the pixel circuit parts PXC and the pixel electrodes 111 may be electrically connected in a one-to-one correspondence. Each of the pixel circuit parts PXC may apply a pixel voltage or an anode voltage to the pixel electrode 111.

Each of the pixel electrodes 111 may be disposed on the corresponding pixel circuit part PXC. Each of the pixel electrodes 111 may be an exposed electrode exposed from the pixel circuit part PXC. For example, each of the pixel electrodes 111 may protrude from the top surface of the pixel circuit part PXC. Each of the pixel electrodes 111 may be integral with (or integrally formed with) the pixel circuit part PXC. Each of the pixel electrodes 111 may be supplied with a pixel voltage or an anode voltage from the pixel circuit part PXC. The pixel electrodes 111 may include aluminum (Al).

The light emitting element layer 120 may be a layer that emits light, including the first light emitting elements LE1, the second light emitting elements LE2, and the third light emitting elements LE3. The light emitting element layer 120 may include an insulating layer INS, the first light emitting elements LE1, the second light emitting elements LE2, the third light emitting elements LE3, bonding electrodes AE, first adhesive layers AL1, second adhesive layers AL2, a connection electrode CNE, the common electrode CE, and the planarization layer PLA.

Each of the bonding electrodes AE may be disposed on the corresponding pixel electrode 111. For example, the bonding electrodes AE may be electrically connected to the pixel electrodes 111 in a one-to-one correspondence. The bonding electrode AE may serve as a bonding metal for adhering (or bonding) the pixel electrode 111 to the first light emitting element LE1, the pixel electrode 111 to the second light emitting element LE2, or the pixel electrode 111 to the third light emitting element LE3 in a fabricating process. For example, the bonding electrodes AE may include at least one of gold (Au), copper (Cu), aluminum (Al), and tin (Sn). As another example, the bonding electrodes AE may include a first layer including at least one of gold (Au), copper (Cu), aluminum (Al), and tin (Sn) and a second layer including another one of gold (Au), copper (Cu), aluminum (Al), and tin (Sn). In this case, the second layer may be disposed on the first layer. As another example, the bonding electrode AE may include a transparent conductive oxide such as indium tin oxide (ITO) or indium zinc oxide (IZO).

The insulating layer INS may be disposed on at least a portion of the substrate SUB on which the bonding electrodes AE are not disposed. The bonding electrodes AE and the insulating layer INS may not overlap each other in the third direction DR3. The insulating layer INS may contact the side surface of each of the bonding electrodes AE. The top surfaces of the bonding electrodes AE and the top surface of the insulating layer INS may be flat. The insulating layer INS may be formed of an inorganic layer such as a silicon oxide (SiO₂) layer, an aluminum oxide (Al₂O₃) layer, or a hafnium oxide (HfOₓ) layer.

Each of the first light emitting elements LE1, the second light emitting elements LE2, and the third light emitting elements LE3 may be disposed on the corresponding bonding electrode AE. Each of the first light emitting elements LE1, the second light emitting elements LE2, and the third light emitting elements LE3 may be a vertical light emitting diode element extending in the third direction DR3. For example, a length, in the third direction DR3, of each of the first light emitting elements LE1, the second light emitting elements LE2, and the third light emitting elements LE3 may be greater than a length thereof in the horizontal direction. The length in the horizontal direction indicates a length thereof in the first direction DR1 or a length thereof in the second direction DR2.

The area of the top surface of each of the first light emitting elements LE1, the second light emitting elements LE2, and the third light emitting elements LE3 may be smaller than the area of the bottom surface thereof. Each of the first light emitting elements LE1, the second light emitting elements LE2, and the third light emitting elements LE3 may have a shape of a truncated cone in which an area of a top surface is smaller than an area of a bottom surface. In this case, a cross section of each of the first light emitting elements LE1, the second light emitting elements LE2, and the third light emitting elements LE3 may have a trapezoidal shape.

The maximum width of the first light emitting element LE1, the maximum width of the second light emitting element LE2, and the maximum width of the third light emitting element LE3 may be substantially the same, but the embodiment of the specification is not limited thereto. For example, a maximum length L11 of the first light emitting element LE1 in the first direction DR1, a maximum length L12 of the second light emitting element LE2 in the first direction DR1, and a maximum length L13 of the third light emitting element LE3 in the first direction DR1 may be substantially the same, but the embodiment of the specification is not limited thereto. In addition, the maximum length L11 of the first light emitting element LE1 in the second direction DR2, the maximum length L12 of the second light emitting element LE2 in the second direction DR2, and the maximum length L13 of the third light emitting element LE3 in the second direction DR2 may be substantially the same, but the embodiment of the specification is not limited thereto.

Each of the first light emitting elements LE1, the second light emitting elements LE2, and the third light emitting elements LE3 may include a first sub light emitting element SLE1, a second sub light emitting element SLE2, and a third sub light emitting element SLE3. The connection electrode CNE may include first connection electrodes CE1, second connection electrodes CE2, and third connection electrodes CE3.

Each of the first sub light emitting element SLE1, the second sub light emitting element SLE2, and the third sub light emitting element SLE3 may be a micro light emitting diode element or a nano light emitting diode element. The first sub light emitting element SLE1 may be disposed on the bonding electrode AE, the second sub light emitting element SLE2 may be disposed on the first sub light emitting element SLE1, and the third sub light emitting element SLE3 may be disposed on the second sub light emitting element SLE2. In this case, each of the first light emitting elements LE1, the second light emitting elements LE2, and the third light emitting elements LE3 has a shape of a truncated cone in which an area of a top surface is smaller than an area of a bottom surface, and thus in case that the size of each of the first light emitting elements LE1, the second light emitting elements LE2, and the third light emitting elements LE3 is the same, the area of the first sub light emitting element SLE1 may be larger than the area of the second sub light emitting element SLE2, and the area of the second sub light emitting element SLE2 may be larger than the area of the third sub light emitting element SLE3.

Since the first sub light emitting element SLE1 emits a first light (e.g., light of a red wavelength band), the light emission efficiency of the first sub light emitting element SLE1 may be lower than the light emission efficiency of the second sub light emitting element SLE2 that emits a second light (e.g., light of a green wavelength band) and the third sub light emitting element SLE3 that emits a third light (e.g., light of a blue wavelength band). Accordingly, the first sub light emitting element SLE1 may have a larger area than that of the second sub light emitting element SLE2 and the third sub light emitting element SLE3, and thus the first sub light emitting element SLE1 may be disposed at the lowermost portion of the first sub light emitting element SLE1, the second sub light emitting element SLE2, and the third sub light emitting element SLE3.

In addition, the light transmittance of the third sub light emitting element SLE3 may be higher than the light transmittance of the first sub light emitting element SLE1 and the light transmittance of the second sub light emitting element SLE2. Accordingly, the third sub light emitting element SLE3 may be disposed at the uppermost portion of the first sub light emitting element SLE1, the second sub light emitting element SLE2, and the third sub light emitting element SLE3.

However, the stacking order of the first sub light emitting element SLE1, the second sub light emitting element SLE2, and the third sub light emitting element SLE3 is not limited to that illustrated in FIGS. 5 to 8. For example, among the first sub light emitting element SLE1, the second sub light emitting element SLE2, and the third sub light emitting element SLE3, the third sub light emitting element SLE3 may be disposed at the uppermost portion, and the second sub light emitting element SLE2 may be disposed at the lowermost portion. As another example, among the first sub light emitting element SLE1, the second sub light emitting element SLE2, and the third sub light emitting element SLE3, the second sub light emitting element SLE2 may be disposed at the uppermost portion, and the third sub light emitting element SLE3 may be disposed at the lowermost portion. As another example, among the first sub light emitting element SLE1, the second sub light emitting element SLE2, and the third sub light emitting element SLE3, the second sub light emitting element SLE2 may be disposed at the uppermost portion, and the first sub light emitting element SLE1 may be disposed at the lowermost portion. As another example, among the first sub light emitting element SLE1, the second sub light emitting element SLE2, and the third sub light emitting element SLE3, the first sub light emitting element SLE1 may be disposed at the uppermost portion, and the second sub light emitting element SLE2 may be disposed at the lowermost portion. As another example, among the first sub light emitting element SLE1, the second sub light emitting element SLE2, and the third sub light emitting element SLE3, the first sub light emitting element SLE1 may be disposed at the uppermost portion, and the third sub light emitting element SLE3 may be disposed at the lowermost portion.

The first sub light emitting element SLE1 may include a first p-type semiconductor layer PSEM1, a first active layer MQW1, and a first n-type semiconductor layer NSEM1 sequentially stacked in the third direction DR3 as illustrated in FIG. 6. The second sub light emitting element SLE2 may include a second p-type semiconductor layer PSEM2, a second active layer MQW2, and a second n-type semiconductor layer NSEM2 sequentially stacked in the third direction DR3 as illustrated in FIG. . The third sub light emitting element SLE3 may include a third p-type semiconductor layer PSEM3, a third active layer MQW3, and a third n-type semiconductor layer NSEM3 sequentially stacked in the third direction DR3 as illustrated in FIG. 7.

Each of the first p-type semiconductor layer PSEM1, the second p-type semiconductor layer PSEM2, and the third p-type semiconductor layer PSEM3 may be disposed on the bonding electrode AE. Each of the first p-type semiconductor layer PSEM1, the second p-type semiconductor layer PSEM2, and the third p-type semiconductor layer PSEM3 may be a semiconductor layer doped with a first conductivity-type dopant such as Mg, Zn, Ca, Se, and Ba. For example, each of the first p-type semiconductor layer PSEM1, the second p-type semiconductor layer PSEM2, and the third p-type semiconductor layer PSEM3 may be p-GaN doped with p-type Mg. Each of the first p-type semiconductor layer PSEM1, the second p-type semiconductor layer PSEM2, and the third p-type semiconductor layer PSEM3 may have a thickness of approximately 30 nm to approximately 200 nm.

An electron blocking layer may be disposed on each of the first p-type semiconductor layer PSEM1, the second p-type semiconductor layer PSEM2, and the third p-type semiconductor layer PSEM3. The electron blocking layer may be a layer for suppressing or preventing too many electrons from flowing into the first active layer MQW1, the second active layer MQW2, or the third active layer MQW3. For example, the electron blocking layer may be p-AlGaN doped with p-type Mg. The thickness of the electron blocking layer may be approximately 10 nm to approximately 50 nm. The electron blocking layer may be omitted.

The first active layer MQW1 may be disposed on the first p-type semiconductor layer PSEM1, the second active layer MQW2 may be disposed on the second p-type semiconductor layer PSEM2, and the third active layer MQW3 may be disposed on the third p-type semiconductor layer PSEM3.

The first active layer MQW1 may emit light by combining electron-hole pairs according to an electrical signal applied thereto through the first p-type semiconductor layer PSEM1 and the first n-type semiconductor layer NSEM1. The first active layer MQW1 may emit first light having a main peak wavelength in a range of approximately 600 nm to approximately 750 nm, for example, light in a red wavelength band.

The second active layer MQW2 may emit light by combining electron-hole pairs according to an electrical signal applied thereto through the second p-type semiconductor layer PSEM2 and the second n-type semiconductor layer NSEM2. The second active layer MQW2 may emit second light having a main peak wavelength in a range of approximately 480 nm to approximately 560 nm, for example, light in a green wavelength band.

The third active layer MQW3 may emit light by combining electron-hole pairs according to an electrical signal applied thereto through the third p-type semiconductor layer PSEM3 and the third n-type semiconductor layer NSEM3. The third active layer MQW3 may emit third light having a main peak wavelength in a range of approximately 370 nm to approximately 460 nm, for example, light in a blue wavelength band.

Each of the first active layer MQW1, the second active layer MQW2, and the third active layer MQW3 may include a material having a single or multiple quantum well structure. In case that each of the first active layer MQW1, the second active layer MQW2, and the third active layer MQW3 includes a material having a multiple quantum well structure, well layers and barrier layers may be alternately stacked with each other to form a structure. In this case, the first active layer MQW1 may include InGaN or GaAs, and the second active layer MQW2 and the third active layer MQW3 may include InGaN, but the disclosure is not limited thereto.

The color of the light emitted from the active layer (e.g., first to third active layers MQW1, MQW2, and MQW3) may vary depending on the content of indium (In). For example, as the content of indium (In) increases, the wavelength band of light emitted from the active layer may shift to a red wavelength band, and as the content of indium (In) decreases, the wavelength band of light emitted from the active layer may shift to a blue wavelength band. Accordingly, in case that each of the first active layer MQW1, the second active layer MQW2, and the third active layer MQW3 includes InGaN, the content of indium (In) in the first active layer MQW1 may be higher than the content of indium (In) in the second active layer MQW2, and the content of indium (In) in the second active layer MQW2 may be higher than the content of indium (In) in the third active layer MQW3. For example, the content of indium (In) in the third active layer MQW3 may be approximately 15%, the content of indium (In) in the second active layer MQW2 may be approximately 25%, and the content of indium (In) in the first active layer MQW1 may be approximately 35% or more.

A superlattice layer may be disposed on each of the first active layer MQW1, the second active layer MQW2, and the third active layer MQW3. The superlattice layer may be a layer to relieve stress between the first active layer MQW1 and the first n-type semiconductor layer NSEM1, stress between the second active layer MQW2 and the second n-type semiconductor layer NSEM2, and stress between the third active layer MQW3 and the third n-type semiconductor layer NSEM3. For example, the superlattice layer may be formed of InGaN or GaN. The thickness of the superlattice layer may be approximately 50 nm to approximately 200 nm. The superlattice layer may be omitted.

The first n-type semiconductor layer NSEM1 may be disposed on the first active layer MQW1, the second n-type semiconductor layer NSEM2 may be disposed on the second active layer MQW2, and the third n-type semiconductor layer NSEM3 may be disposed on the third active layer MQW3. Each of the first n-type semiconductor layer NSEM1, the second n-type semiconductor layer NSEM2, and the third n-type semiconductor layer NSEM3 may be a semiconductor layer doped with a second conductivity-type dopant such as Si, Ge, and Sn. For example, each of the first n-type semiconductor layer NSEM1, the second n-type semiconductor layer NSEM2, and the third n-type semiconductor layer NSEM3 may be n-GaN doped with n-type Si. Each of the first n-type semiconductor layer NSEM1, the second n-type semiconductor layer NSEM2, and the third n-type semiconductor layer NSEM3 may have a thickness of approximately 500 nm to approximately 1 μm.

For example, since the first sub light emitting element SLE1 includes the first active layer MQW1, the first light may be emitted in case that a current flows through the first p-type semiconductor layer PSEM1, the first active layer MQW1, and the first n-type semiconductor layer NSEM1. For example, since the second sub light emitting element SLE2 includes the second active layer MQW2, the second light may be emitted in case that a current flows through the second p-type semiconductor layer PSEM2, the second active layer MQW2, and the second n-type semiconductor layer NSEM2. For example, since the third sub light emitting element SLE3 includes the third active layer MQW3, the third light may be emitted in case that a current flows through the third p-type semiconductor layer PSEM3, the third active layer MQW3, and the third n-type semiconductor layer NSEM3.

The first adhesive layer AL1 may be disposed between the first sub light emitting element SLE1 and the second sub light emitting element SLE2. For example, the first adhesive layer AL1 may be disposed between the first n-type semiconductor layer NSEM1 of the first sub light emitting element SLE1 and the second p-type semiconductor layer PSEM2 of the second sub light emitting element SLE2. The first adhesive layer AL1 may be formed of transparent conductive oxide (TCO) such as indium tin oxide (ITO) or indium zinc oxide (IZO) to transmit the first light of the first sub light emitting element SLE1.

The second adhesive layer AL2 may be disposed between the second sub light emitting element SLE2 and the third sub light emitting element SLE3. For example, the second adhesive layer AL2 may be disposed between the second n-type semiconductor layer NSEM2 of the second sub light emitting element SLE2 and the third p-type semiconductor layer PSEM3 of the third sub light emitting element SLE3. The second adhesive layer AL2 may be formed of transparent conductive oxide such as indium tin oxide (ITO) or indium zinc oxide (IZO) to transmit the first light of the first sub light emitting element SLE1 and the second light of the second sub light emitting element SLE2. The thickness of the second adhesive layer AL2 may be approximately 15 nm, but the embodiment of the specification is not limited thereto.

The first light emitting element LE1 may further include the first connection electrode CE1. The first connection electrode CE1 may be disposed on the side surface of the first sub light emitting element SLE1 of the first light emitting element LE1, the side surface of the second sub light emitting element SLE2 thereof, and the side surface of the third sub light emitting element SLE3 thereof

For example, the first connection electrode CE1 may be disposed to cover (or overlap in a plan view) at least a portion of a side surface of the first sub light emitting element SLE1. The first connection electrode CE1 may be disposed to cover the entire side surface of the second sub light emitting element SLE2 and the entire side surface of the third sub light emitting element SLE3. The first connection electrode CE1 may be disposed on the top surface of the third sub light emitting element SLE3. The first connection electrode CE1 may be disposed on the side surface of the first adhesive layer AL1 and the side surface of the second adhesive layer AL2.

The first connection electrode CE1 may be disposed on the side surface of the first n-type semiconductor layer NSEM1, the side surface of the first adhesive layer AL1, the side surface of the second p-type semiconductor layer PSEM2, the side surface of the second active layer MQW2, the side surface of the second n-type semiconductor layer NSEM2, the side surface of the second adhesive layer AL2, the side surface of the third p-type semiconductor layer PSEM3, the side surface of the third active layer MQW3, and the side surface of the third n-type semiconductor layer NSEM3. In addition, the first connection electrode CE1 may be disposed on the top surface of the third n-type semiconductor layer NSEM3. The first n-type semiconductor layer NSEM1, the first adhesive layer AL1, the second p-type semiconductor layer PSEM2, the second active layer MQW2, the second n-type semiconductor layer NSEM2, the second adhesive layer AL2, the third p-type semiconductor layer PSEM3, the third active layer MQW3, and the third n-type semiconductor layer NSEM3 may be short-circuited by the first connection electrode CE1.

The second light emitting element LE2 may further include the second connection electrode CE2. The second connection electrode CE2 may be disposed on the side surface of the first sub light emitting element SLE1 of the second light emitting element LE2, the side surface of the second sub light emitting element SLE2 thereof, and the side surface of the third sub light emitting element SLE3 thereof.

For example, the second connection electrode CE2 may include a first sub connection electrode SCE1 covering the entire side surface of the first sub light emitting element SLE1 and at least a portion of the side surface of the second sub light emitting element SLE2, and a second sub connection electrode SCE2 covering at least another portion of the side surface of the second sub light emitting element SLE2 and the entire side surface of the third light emitting element SLE3. The second sub connection electrode SCE2 may be disposed on the top surface of the third sub light emitting element SLE3. The first sub connection electrode SCE1 may be disposed on the side surface of the first adhesive layer AL1, and the second sub connection electrode SCE2 may be disposed on the side surface of the second adhesive layer AL2.

The first sub connection electrode SCE1 may be disposed on the side surface of the first p-type semiconductor layer PSEM1, the side surface of the first active layer MQW1, the side surface of the first n-type semiconductor layer NSEM1, the side surface of the first adhesive layer AL1, and the side surface of the second p-type semiconductor layer PSEM2. Due to the first sub connection electrode SCE1, the first p-type semiconductor layer PSEM1, the first active layer MQW1, the first n-type semiconductor layer NSEM1, the first adhesive layer AL1, and the second p-type semiconductor layer PSEM2 may be short-circuited.

The second sub connection electrode SCE2 may be disposed on the side surface of the second n-type semiconductor layer NSEM2, the side surface of the second adhesive layer AL2, the side surface of the third p-type semiconductor layer PSEM3, the side surface of the third active layer MQW3, and the side surface of the third n-type semiconductor layer NSEM3. In addition, the second sub connection electrode SCE2 may be disposed on the top surface of the third n-type semiconductor layer NSEM3. Due to the second sub connection electrode SCE2, the second n-type semiconductor layer NSEM2, the second adhesive layer AL2, the third p-type semiconductor layer PSEM3, the third active layer MQW3, and the third n-type semiconductor layer NSEM3 may be short-circuited.

The third light emitting element LE3 may further include the third connection electrode CE3. The third connection electrode CE3 may be disposed on the side surface of the first sub light emitting element SLE1 of the third light emitting element LE3, the side surface of the second sub light emitting element SLE2 thereof, and the side surface of the third sub light emitting element SLE3 thereof. The third connection electrode CE3 may be apart from the common electrode CE.

For example, the third connection electrode CE3 may be disposed to cover (or in a plan view) at least a portion of the side surface of the third sub light emitting element SLE3. The third connection electrode CE3 may be disposed to cover the entire side surface of the first sub light emitting element SLE1 and the entire side surface of the second sub light emitting element SLE2. The third connection electrode CE3 may be disposed on the side surface of the first adhesive layer AL1 and the side surface of the second adhesive layer AL2.

The third connection electrode CE3 may be disposed on the side surface of the first p-type semiconductor layer PSEM1, the side surface of the first active layer MQW1, the side surface of the first n-type semiconductor layer NSEM1, the side surface of the first adhesive layer AL1, the side surface of the second p-type semiconductor layer PSEM2, the side surface of the second active layer MQW2, the side surface of the second n-type semiconductor layer NSEM2, the side surface of the second adhesive layer AL2, and the side surface of the third p-type semiconductor layer PSEM3. Due to the third connection electrode CE3, the first p-type semiconductor layer PSEM1, the first active layer MQW1, the first n-type semiconductor layer NSEM1, the first adhesive layer AL1, the second p-type semiconductor layer PSEM2, the second active layer MQW2, the second n-type semiconductor layer NSEM2, and the third p-type semiconductor layer PSEM3 may be short-circuited.

For example, due to the third connection electrode CE3, only the third sub light emitting element SLE3 of the third light emitting element LE3 emits light, and the first sub light emitting element SLE1 and the second sub light emitting element SLE2 do not emit light. Accordingly, the third light emitted from the third sub light emitting element SLE3 may be outputted from the third light emitting element LE3.

Each of the first connection electrode CE1, the second connection electrode CE2, and the third connection electrode CE may include a transparent conductive oxide such as indium tin oxide (ITO) or indium zinc oxide (IZO). For example, each of the first connection electrode CE1, the second connection electrode CE2, and the third connection electrode CE, and the first adhesive layer AL1 and the second adhesive layer AL2 may include a same material.

The inclined angle (hereinafter referred to as a “taper angle” 0) of the side surface of each of the first light emitting elements LE1, the second light emitting elements LE2, and the third light emitting elements LE3 may be set in consideration of process limitations of the first sub connection electrode SCE1 and the second sub connection electrode SCE2. For example, as the minimum separation distance between the first sub connection electrode SCE1 and the second sub connection electrode SCE2 decreases, the taper angle of the side surface of each of the first light emitting elements LE1, the second light emitting elements LE2, and the third light emitting elements LE3 may be increased. For example, the minimum separation distance between the first sub connection electrode SCE1 and the second sub connection electrode SCE2 may be about 0.1 μm to about 1 μm, but the disclosure is not limited thereto.

The first adhesive layer AL1 is a layer for adhesion of the first sub light emitting element SLE1 and the second sub light emitting element SLE2, the second adhesive layer AL2 is a layer for adhesion of the second sub light emitting element SLE2 and the third sub light emitting element SLE3, and on the other hand, the first connection electrode CE1, the second connection electrode CE2, and the third connection electrode CE3 are electrodes for forming a short circuit. In case that the thickness of each of the first connection electrode CE1, the second connection electrode CE2, and the third connection electrode CE3 is low, conductivity may be low due to resistance. Accordingly, in case that the first connection electrode CE1, the second connection electrode CE2, the third connection electrode CE, the first adhesive layer AL1, and the second adhesive layer AL2 include a transparent conductive oxide such as indium tin oxide (ITO) or indium zinc oxide (IZO), the thickness of each of the first connection electrode CE1, the second connection electrode CE2, and the third connection electrode CE3 may be thicker than the thickness of each of the first adhesive layer AL1 and the second adhesive layer AL2. For example, the thickness of each of the first connection electrode CE1, the second connection electrode CE2, and the third connection electrode CE3 may be approximately 100 nm, but the embodiment of the specification is not limited thereto.

The planarization layer PLA may fill a space between the light emitting elements LE1, LE2, and LE3 to planarize a step caused by the first to third light emitting elements LE1, LE2, and LE3. The planarization layer PLA may cover the side surface of each of the first light emitting elements LE1, the side surface of each of the second light emitting elements LE2, and the side surface of each of the third light emitting elements LE3. The planarization layer PLA does not cover the top surface of each of the first light emitting elements LE1, the top surface of each of the second light emitting elements LE2, and the top surface of each of the third light emitting elements LE3. For example, the planarization layer PLA does not cover the top surface of the first connection electrode CE1 of each of the first light emitting elements LE1 and the top surface of the second connection electrode CE2 of each of the second light emitting elements LE2. In addition, the planarization layer PLA does not cover the top surface of the third n-type semiconductor layer NSEM3 of each of the third light emitting elements LE3.

The common electrode CE may be disposed on the top surface of each of the first to third light emitting elements LE1, LE2, and LE3 and the top surface of the planarization layer PLA. The common electrode CE may be disposed to cover the top surface of each of the first to third light emitting elements LE1, LE2, and LE3 and the top surface of the planarization layer PLA. The common electrode CE may contact the first connection electrode CE1 of each of the first light emitting elements LE1, the second sub connection electrode SCE2 of the second connection electrode CE2 of each of the second light emitting elements LE2, and the third n-type semiconductor layer NSEM3 of the third light emitting element LE3.

The common electrode CE may include a transparent conductive material. The common electrode CE may be formed of transparent conductive oxide such as indium tin oxide (ITO) or indium zinc oxide (IZO). The thickness of the common electrode CE may be approximately 100 nm, but the embodiment of the specification is not limited thereto.

As illustrated in FIGS. 5 and 6, the first n-type semiconductor layer NSEM1, the first adhesive layer AL1, the second p-type semiconductor layer PSEM2, the second active layer MQW2, the second n-type semiconductor layer NSEM2, the second adhesive layer AL2, the third p-type semiconductor layer PSEM3, the third active layer MQW3, and the third n-type semiconductor layer NSEM3, of the first light emitting element LE1 may be short-circuited by the first connection electrode CE1. The first n-type semiconductor layer NSEM1, the first adhesive layer AL1, the second p-type semiconductor layer PSEM2, the second active layer MQW2, the second n-type semiconductor layer NSEM2, the second adhesive layer AL2, the third p-type semiconductor layer PSEM3, the third active layer MQW3, and the third n-type semiconductor layer NSEM3, of the first light emitting element LE1 may be electrically connected to the common electrode CE.

Since the common voltage of the common electrode CE is applied to the second p-type semiconductor layer PSEM2, the second active layer MQW2, and the second n-type semiconductor layer NSEM2, of the first light emitting element LE1, the second active layer MQW2 does not emit light. In addition, since the common voltage of the common electrode CE is applied to the third p-type semiconductor layer PSEM3, the third active layer MQW3, and the third n-type semiconductor layer NSEM3, of the first light emitting element LE1, the third active layer MQW3 does not emit light. In contrast, since the pixel voltage of the pixel electrode 111 is applied to the first p-type semiconductor layer PSEM1 of the first light emitting element LE1, and the common voltage of the common electrode CE is applied to the first n-type semiconductor layer NSEM1 thereof, the first active layer MQW1 may emit the first light.

For example, due to the first connection electrode CE1, only the first sub light emitting element SLE1 of the first light emitting element LE1 emits light, and the second sub light emitting element SLE2 and the third sub light emitting element SLE3 do not emit light. Accordingly, the first light emitted from the first sub light emitting element SLE1 may be outputted from the first light emitting element LE1.

As illustrated in FIGS. 5 and 7, the first p-type semiconductor layer PSEM1, the first active layer MQW1, the first n-type semiconductor layer NSEM1, the first adhesive layer AL1, and the second p-type semiconductor layer PSEM2, of the second light emitting element LE2 may be short-circuited by the first sub connection electrode SCE1. The second n-type semiconductor layer NSEM2, the second adhesive layer AL2, the third p-type semiconductor layer PSEM3, the third active layer MQW3, and the third n-type semiconductor layer NSEM3, of the second light emitting element LE2 may be short-circuited by the second sub connection electrode SCE2.

The first p-type semiconductor layer PSEM1, the first active layer MQW1, the first n-type semiconductor layer NSEM1, and the second p-type semiconductor layer PSEM2, of the second light emitting element LE2 may be electrically connected to the pixel electrode 111. The second n-type semiconductor layer NSEM2, the second adhesive layer AL2, the third p-type semiconductor layer PSEM3, the third active layer MQW3, and the third n-type semiconductor layer NSEM3, of the second light emitting element LE2 may be electrically connected to the common electrode CE.

Since the pixel voltage of the pixel electrode 111 is applied to the first p-type semiconductor layer PSEM1, the first active layer MQW1, and the first n-type semiconductor layer NSEM1, of the second light emitting element LE2, the first active layer MQW1 does not emit light. In addition, since the common voltage of the common electrode CE is applied to the third p-type semiconductor layer PSEM3, the third active layer MQW3, and the third n-type semiconductor layer NSEM3, of the second light emitting element LE2, the third active layer MQW3 does not emit light. In contrast, since the pixel voltage of the pixel electrode 111 is applied to the second p-type semiconductor layer PSEM2 of the second light emitting element LE2, and the common voltage of the common electrode CE is applied to the second n-type semiconductor layer NSEM2 thereof, the second active layer MQW2 may emit the first light.

For example, due to the second connection electrode CE2, only the second sub light emitting element SLE2 of the second light emitting element LE2 emits light, and the first sub light emitting element SLE1 and the third sub light emitting element SLE3 do not emit light. Accordingly, the second light emitted from the second sub light emitting element SLE2 may be outputted from the second light emitting element LE2.

As illustrated in FIGS. 5 and 8, the first p-type semiconductor layer PSEM1, the first active layer MQW1, the first n-type semiconductor layer NSEM1, the first adhesive layer AL1, the second p-type semiconductor layer PSEM2, the second active layer MQW2, the second n-type semiconductor layer NSEM2, the second adhesive layer AL2, and the third p-type semiconductor layer PSEM3, of the third light emitting element LE3 may be short-circuited by the third connection electrode CE3. The first p-type semiconductor layer PSEM1, the first active layer MQW1, the first n-type semiconductor layer NSEM1, the first adhesive layer AL1, the second p-type semiconductor layer PSEM2, the second active layer MQW2, the second n-type semiconductor layer NSEM2, the second adhesive layer AL2, and the third p-type semiconductor layer PSEM3, of the third light emitting element LE3 may be electrically connected to the common electrode CE.

Since the common voltage of the common electrode CE is applied to the first p-type semiconductor layer PSEM1, the first active layer MQW1, and the first n-type semiconductor layer NSEM1, of the third light emitting element LE3, the first active layer MQW1 emits no light. In addition, since the common voltage of the common electrode CE is applied to the second p-type semiconductor layer PSEM2, the second active layer MQW2, and the second n-type semiconductor layer NSEM2, of the third light emitting element LE3, the second active layer MQW2 emits no light. In contrast, since the pixel voltage of the pixel electrode 111 is applied to the third p-type semiconductor layer PSEM3 of the third light emitting element LE3, and the common voltage of the common electrode CE is applied to the third n-type semiconductor layer NSEM3 thereof, the third active layer MQW3 may emit the third light.

For example, due to the third connection electrode CE3, only the third sub light emitting element SLE3 of the third light emitting element LE3 emits light, and the first sub light emitting element SLE1 and the second sub light emitting element SLE2 do not emit light. Accordingly, the third light emitted from the third sub light emitting element SLE3 may be outputted from the third light emitting element LE3.

As illustrated in FIGS. 5 to 8, by including the first light emitting element LE1 emitting the first light, the second light emitting element LE2 emitting the second light, and the third light emitting element LE3 emitting the third light, it is possible to display various colors without a wavelength conversion layer, and moreover, there is no need for a partition wall (or bank) to partition the wavelength conversion layer.

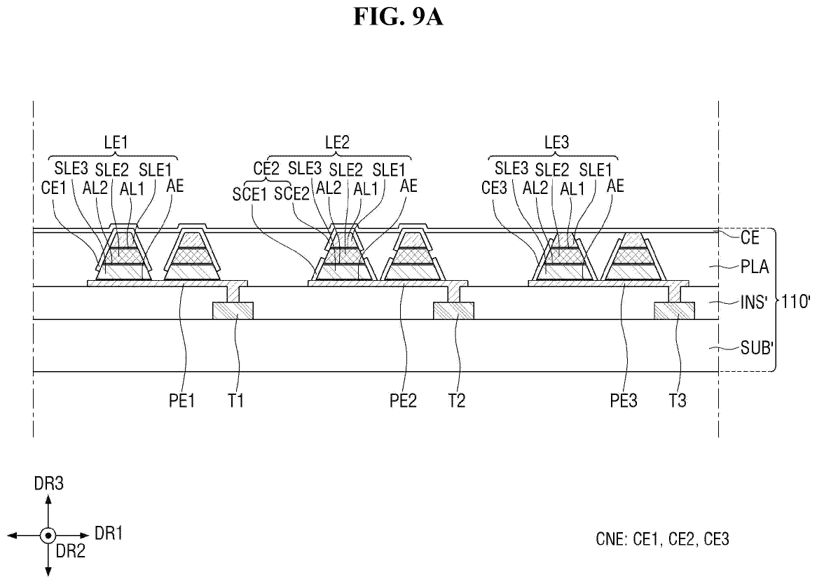

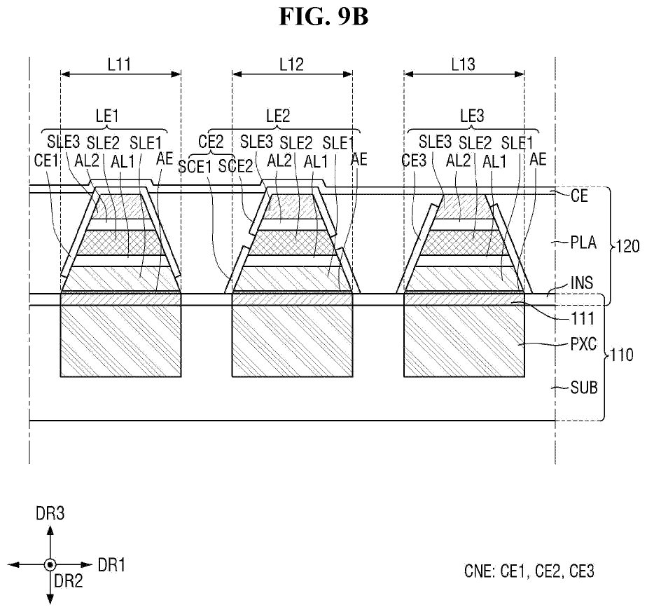

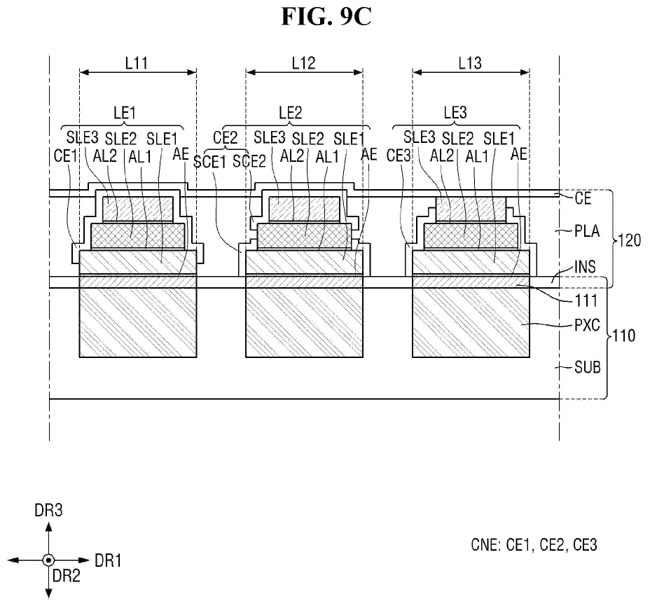

FIG. 9A is a schematic cross-sectional view illustrating an example of a display panel taken along line A-A′ of FIG. 3.

The embodiment of FIG. 9A differs from the embodiment of FIG. 5 in that the display panel 100 includes a thin-film transistor substrate 110′ formed by the thin-film transistor process instead of the semiconductor circuit substrate 110 formed by the semiconductor process using a silicon wafer. With reference to FIG. 9A, repetitive descriptions with respect to the embodiment of FIG. 5 will be omitted.

Referring to FIG. 9A, the thin-film transistor substrate 110′ may include a substrate SUB′, thin film transistors (e.g., first to third transistors) T1, T2, and T3, an insulating layer INS′, a first pixel electrode PE1, and a second pixel electrode PE2, and a third pixel electrode PE3.

The substrate SUB′ may be an insulating substrate. For example, the substrate SUB′ may include a transparent insulating material such as glass, quartz, or the like. As another example, the substrate SUB′ may include plastic such as polyimide. The substrate SUB′ may be a rigid substrate or a flexible substrate that can be curved, bent, folded, or rolled.

The first to third thin-film transistors T1, T2, and T3 may be disposed on the substrate SUB′. The first thin-film transistor T1 may be a transistor electrically connected to the first pixel electrode PEI. The second thin-film transistor T2 may be a transistor electrically connected to the second pixel electrode PE2. The third thin-film transistor T3 may be a transistor electrically connected to the third pixel electrode PE3. Each of the first to third thin-film transistors T1, T2, and T3 may include amorphous silicon, polysilicon, or an oxide semiconductor.

The insulating layer INS′ may be disposed on the first to third thin-film transistors T1, T2, and T3 to planarize a step caused by the first to third thin-film transistors T1, T2, and T3. The insulating layer INS′ may be an organic layer including acrylic resin, epoxy resin, imide resin, or ester resin.

The first pixel electrode PEL the second pixel electrode PE2, and the third pixel electrode PE3 may be disposed on the insulating layer INS′. The first pixel electrode PE1 may penetrate the insulating layer INS′ to be electrically connected to the first thin-film transistor T1, the second pixel electrode PE2 may penetrate the insulating layer INS′ to be electrically connected to the second thin-film transistor T2, and the third pixel electrode PE3 may penetrate the insulating layer INS′ to be electrically connected to the third thin-film transistor T3.

The first pixel electrode PEL the second pixel electrode PE2, and the third pixel electrode PE3 may be formed of a highly reflective metal material such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bonding electrode AE and the first light emitting elements LE1 may be disposed on the first pixel electrode PEL the bonding electrode AE and the second light emitting elements LE2 may be disposed on the second pixel electrode PE2, and the bonding electrode AE and the third light emitting elements LE3 may be disposed on the third pixel electrode PE3. Since the bonding electrode AE, the first light emitting elements LE1, the second light emitting elements LE2, and the third light emitting element LE3 are substantially the same as those described with reference to FIG. 5, the description thereof will be omitted.

Since the planarization layer PLA and the common electrode CE are also substantially the same as those described with reference to FIG. 5, the description thereof will be omitted.

FIG. 9B is a schematic cross-sectional view illustrating another example of a display panel taken along line A-A′ of FIG. 3.

The embodiment of FIG. 9B differs from the embodiment of FIG. 5 in that each of the first adhesive layer AL1 and the second adhesive layer AL2 is a transparent adhesive member having insulating properties instead of transparent conductive oxide. Repetitive descriptions of the parts already described in the embodiment of FIG. 5 will be omitted from those of FIG. 9B.

Referring to FIG. 9B, each of the first adhesive layer AL1 and the second adhesive layer AL2 may be a cured transparent adhesive resin or a cured transparent adhesive film. Each of the first adhesive layer AL1 and the second adhesive layer AL2 may have insulating properties. Each of the first adhesive layer AL1 and the second adhesive layer AL2 may have a thickness greater than the thickness of each of the first connection electrode CE1, the second connection electrode CE2, and the third connection electrode CE3.

FIG. 9C is a schematic cross-sectional view illustrating an example of a display panel taken along line A-A′ of FIG. 3.

to the embodiment of FIG. 9C differs from the embodiment of FIG. 5 at least in that in each of the first light emitting elements LE1, the second light emitting elements LE2, and the third light emitting elements LE3, the first sub light emitting element SLE1, the second sub light emitting element SLE2, and the third sub light emitting element SLE3 have a rectangular cross-sectional shape. Repetitive descriptions of the parts already described in the embodiment of FIG. 5 will be omitted from those of FIG. 9C.

Referring to FIG. 9C, in each of the first light emitting elements LE1, the second light emitting elements LE2, and the third light emitting elements LE3, the size of the first sub light emitting element SLE1 may be larger than the size of the second sub light emitting element SLE2, and the size of the second sub light emitting element SLE2 may be larger than the size of the third sub light emitting element SLE3. For example, in each of the first light emitting elements LE1, the second light emitting elements LE2, and the third light emitting elements LE3, the area of the top surface of the first sub light emitting element SLE1 may be larger than the area of the top surface of the second sub light emitting element SLE2, and the area of the top surface of the second sub light emitting element SLE2 may be larger than the area of the top surface of the third sub light emitting element SLE3.

In each of the first light emitting elements LE1, the second light emitting elements LE2, and the third light emitting elements LE3, a portion of the top surface of the first sub light emitting element SLE1 may be exposed without being covered by the first adhesive layer AL1 and the second sub light emitting element SLE2. In each of the first light emitting elements LE1, the second light emitting elements LE2, and the third light emitting elements LE3, a portion of the top surface of the second sub light emitting element SLE2 may be exposed without being covered by the second adhesive layer AL2 and the third sub light emitting element SLE3.

The first connection electrode CE1 may be disposed on the top surface of the first sub light emitting element SLE1 and the top surface of the second sub light emitting element SLE2. In addition, the first sub connection electrode SCE1 may be disposed on the top surface of the first sub light emitting element SLE1, and the second sub connection electrode SCE2 may be disposed on the top surface of the second sub light emitting element SLE2. In addition, the third connection electrode CE3 may be disposed on the top surface of the first sub light emitting element SLE1 and the top surface of the second sub light emitting element SLE2.

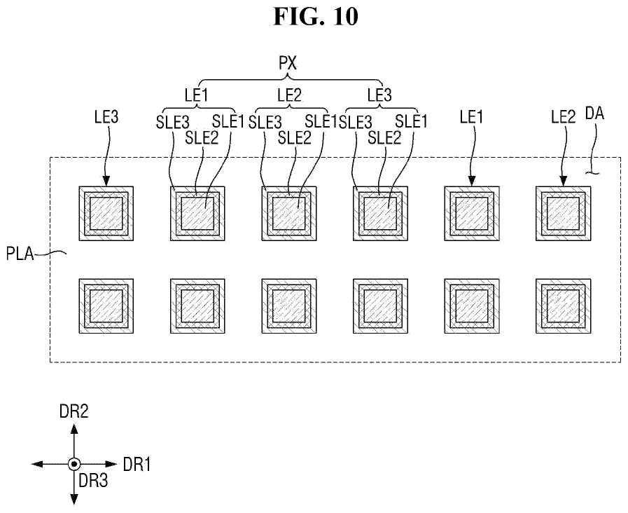

FIG. 10 is a schematic layout view illustrating pixels of a display panel according to still another embodiment.

The embodiment of FIG. 10 differs from the embodiment of FIG. 3 at least in that the top surface of each of the first light emitting elements LE1, the second light emitting elements LE2, and the third light emitting elements LE3, which are exposed without being covered by the planarization layer PLA, has a rectangular planar shape. Repetitive descriptions of the components already described in the embodiment of FIG. 3 will be omitted from those of FIG. 10.

Referring to FIG. 10, each of the first light emitting elements LE1, the second light emitting elements LE2, and the third light emitting elements LE3 may have the shape of a quadrangular truncated pyramid in which an area of a top surface is smaller than an area of a bottom surface. In this case, a cross section of each of the first light emitting elements LE1, the second light emitting elements LE2, and the third light emitting elements LE3 may have a trapezoidal shape.

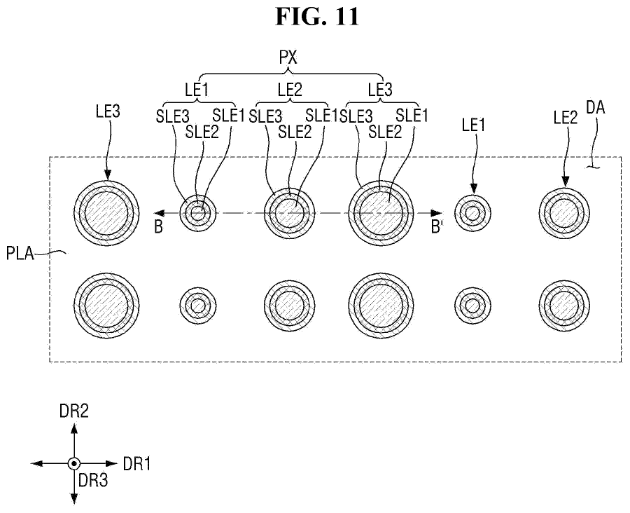

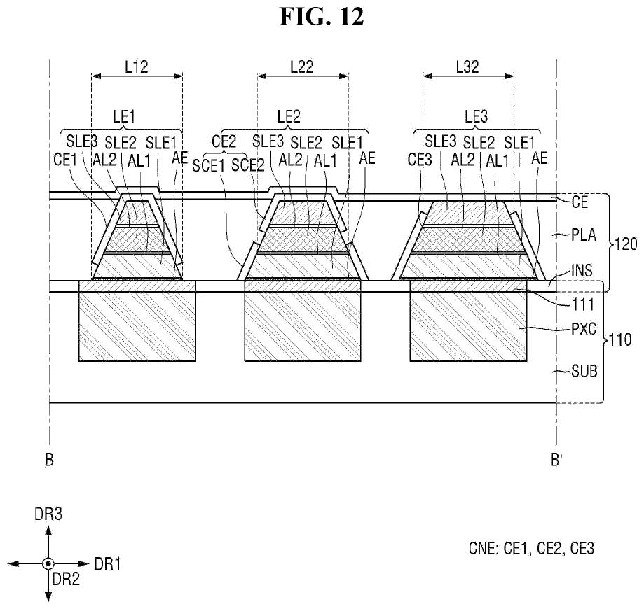

FIG. 11 is a schematic layout view illustrating pixels of a display panel according to still another embodiment. FIG. 12 is a schematic cross-sectional view illustrating an example of a display panel taken along line B-B′ of FIG. 11.

The embodiment of FIGS. 11 and 12 differs from the embodiment of FIGS. 3 and 5 at least in that the size of the first light emitting element LE1, the size of the second light emitting element LE2, and the size of the third light emitting element LE3 are different. Repetitive descriptions of the parts already described in the embodiment of FIGS. 3 and 5 will be omitted from those of FIGS. 11 and 12.

Referring to FIGS. 11 and 12, the area of the top surface of each of the first light emitting elements LE1, the second light emitting elements LE2, and the third light emitting elements LE3 may be smaller than the area of the bottom surface thereof. Each of the first light emitting elements LE1, the second light emitting elements LE2, and the third light emitting elements LE3 may have a shape of a truncated cone in which an area of a top surface is smaller than an area of a bottom surface. In this case, a cross section of each of the first light emitting elements LE1, the second light emitting elements LE2, and the third light emitting elements LE3 may have a trapezoidal shape.

Accordingly, in case that the light emission efficiency of the first sub light emitting element SLE1, the light emission efficiency of the second sub light emitting element SLE2, and the light emission efficiency of the third sub light emitting element SLE3 are similar, the area of the first sub light emitting element SLE1 emitting the first light in the first light emitting element LE1, the area of the second sub light emitting element SLE2 emitting the second light in the second light emitting element LE2, and the area of the third sub light emitting element SLE3 emitting the third light in the third light emitting element LE3 may be the same.

A maximum length L12 in the first direction DR1 of the first sub light emitting element SLE1 of the first light emitting element LE1, a maximum length L22 in the first direction DR1 of the second sub light emitting element SLE2 of the second light emitting element LE2, and a maximum length L32 in the first direction DR1 of the third sub light emitting element SLE3 of the third light emitting element LE3 may be substantially the same. In addition, the maximum length in the second direction DR2 of the first sub light emitting element SLE1 of the first light emitting element LE1, the maximum length in the second direction DR2 of the second sub light emitting element SLE2 of the second light emitting element LE2, and the maximum length in the second direction DR2 of the third sub light emitting element SLE3 of the third light emitting element LE3 may be substantially the same.

In case that each of the first light emitting elements LE1, the second light emitting elements LE2, and the third light emitting elements LE3 has a shape of a truncated cone in which an area of a top surface is smaller than an area of a bottom surface, and the second sub light emitting element SLE2 is disposed on the first sub light emitting element SLE1 and the third sub light emitting element SLE3 is disposed on the second sub light emitting element SLE2, in a case where the area of the first sub light emitting element SLE1 of the first light emitting element LE1, the area of the second sub light emitting element SLE2 of the second light emitting element LE2, and the area of the third sub light emitting element SLE3 of the third light emitting element LE3 are the same, the size of the first light emitting element LE1 may be the smallest, and the size of the third light emitting element LE3 may be the largest. Accordingly, the area of the top surface of the second light emitting element LE2 exposed without being covered by the planarization layer PLA may be larger than the area of the top surface of the first light emitting element LE1 exposed without being covered by the planarization layer PLA. The area of the top surface of the third light emitting element LE3 exposed without being covered by the planarization layer PLA may be larger than the area of the top surface of the second light emitting element LE2 exposed without being covered by the planarization layer PLA.

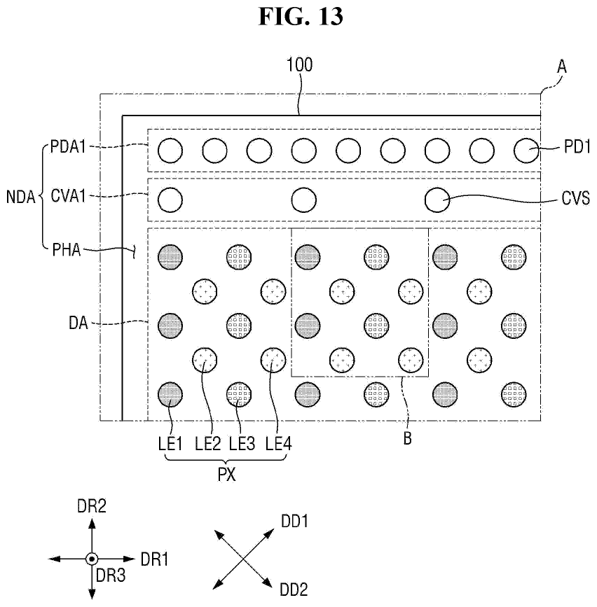

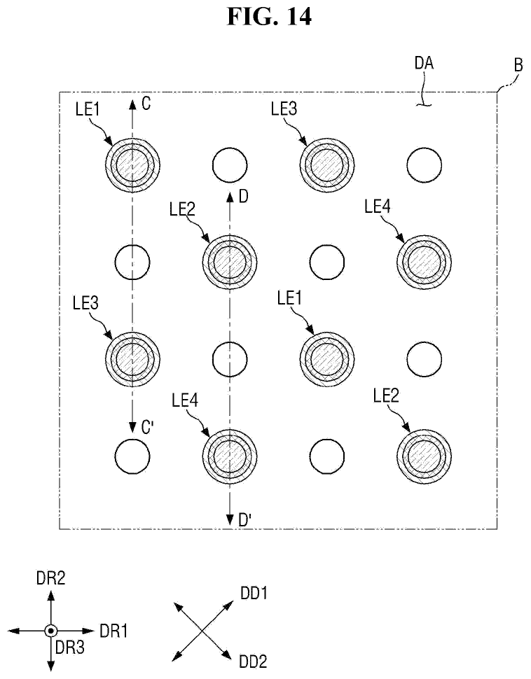

FIG. 13 is a schematic layout view illustrating another example of area A of FIG. 1 in detail. FIG. 14 is a schematic layout view illustrating pixels of a display panel according to still another embodiment.

The embodiment of FIGS. 13 and 14 differs from the embodiment of FIGS. 2 and 3 in that each of the pixels PX includes four light emitting elements LE1, LE2, LE3, and LE4. Repetitive descriptions of the parts already described in the embodiment of FIGS. 2 and 3 will be omitted from those of FIGS. 13 and 14.

Referring to FIGS. 13 and 14, each of the pixels PX may include the first light emitting element LE1 emitting the first light, the second light emitting element LE2 emitting the second light, the third light emitting element LE3 emitting the third light, the fourth light emitting element LE4 emitting the second light, and a common connection portion CCT.

In the display area DA, the first light emitting elements LE1 and the third light emitting elements LE3 may be alternately disposed in the first direction DR1 and the second direction DR2. In the display area DA, the common connection portion CCT may be disposed between the first light emitting element LE1 and the third light emitting element LE3 adjacent to each other in the first direction DR1 or the second direction DR2.

In the display area DA, the second light emitting elements LE2 and the fourth light emitting elements LE4 may be alternately disposed in the first direction DR1 and the second direction DR2. In the display area DA, the common connection portion CCT may be disposed between the second light emitting element LE2 and the fourth light emitting element LE4 adjacent to each other in the first direction DR1 or the second direction DR2.

In the display area DA, the first light emitting elements LE1, the second light emitting elements LE2, the third light emitting elements LE3, and the fourth light emitting elements LE4 may be alternately disposed in a first diagonal direction DD1 and a second diagonal direction DD2. In the display area DA, the common connection portions CCT may be alternately disposed in the first diagonal direction DD1 and the second diagonal direction DD2. The first diagonal direction DD1 may be a diagonal direction between the first direction DR1 and the second direction DR2, and the second diagonal direction DD2 may be a direction perpendicular to the first diagonal direction DD 1.

In each of the pixels PX, the first light emitting element LE1 and the third light emitting element LE3 may be disposed in the first direction DR1, and the second light emitting element LE2 and the fourth light emitting element LE4 may be disposed in the first direction DR1. In each of the pixels PX, the first light emitting element LE1 and the second light emitting element LE2 may be disposed in the first diagonal direction DD1, the second light emitting element LE2 and the third light emitting element LE3 may be disposed in the second diagonal direction DD2, and the third light emitting element LE3 and the fourth light emitting element LE4 may be disposed in the first diagonal direction DD1.

The fourth light emitting element LE4 may be substantially the same as the second light emitting element LE2. For example, the fourth light emitting element LE4 may emit the second light, and the fourth light emitting element LE4 and the second light emitting element LE2 may have a same structure. The first light may be light in a red wavelength band, the second light may be light in a green wavelength band, the third light may be light in a blue wavelength band, and the fourth light may be light in a green wavelength band.

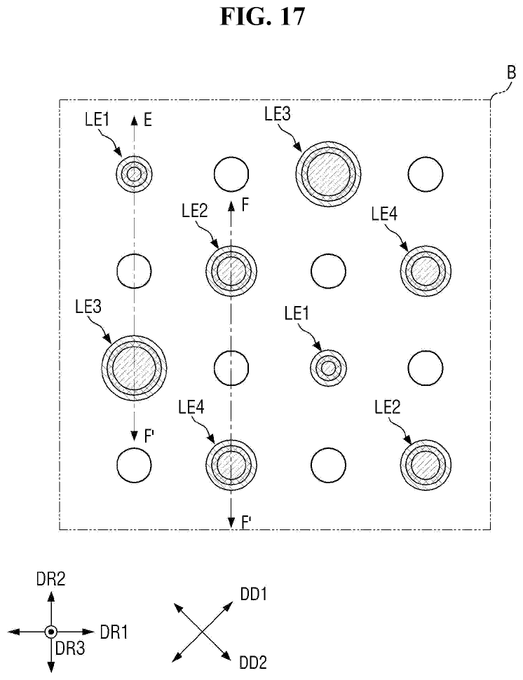

The area of the first light emitting element LE1, the area of the second light emitting element LE2, the area of the third light emitting element LE3, and the area of the fourth light emitting element LE4 may be substantially the same, but the embodiment of the specification is not limited thereto. For example, as illustrated in FIG. 17, the area of the first light emitting element LE1, the area of the second light emitting element LE2, and the area of the third light emitting element LE3 may be different, and the area of the second light emitting element LE2 may be equal to the area of the fourth light emitting element LE4.

In addition, the distance between the first light emitting element LE1 and the second light emitting element LE2 adjacent to each other, the distance between the second light emitting element LE2 and the third light emitting element LE3 adjacent to each other, the distance between the first light emitting element LE1 and the fourth light emitting element LE4 adjacent to each other, and the distance between the third light emitting element LE3 and the fourth light emitting element LE4 adjacent to each other may be substantially the same, but the embodiment of the specification is not limited thereto. For example, the distance between the first light emitting element LE1 and the second light emitting element LE2 adjacent to each other may be different from the distance between the second light emitting element LE2 and the third light emitting element LE3 adjacent to each other, and the distance between the first light emitting element LE1 and the fourth light emitting element LE4 adjacent to each other may be different from the distance between the third light emitting element LE3 and the fourth light emitting element LE4 adjacent to each other. In this case, the distance between the first light emitting element LE1 and the second light emitting element LE2 adjacent to each other and the distance between the first light emitting element LE1 and the fourth light emitting element LE4 adjacent to each other may be substantially the same, and the distance between the second light emitting element LE2 and the third light emitting element LE3 adjacent to each other and the distance between the third light emitting element LE3 and the fourth light emitting element LE4 adjacent to each other may be substantially the same.

In addition, the first light emitting element LE1 may emit the first light, the second light emitting element LE2 and the fourth light emitting element LE4 may emit the second light, and the third light emitting element LE3 may emit the third light, but the embodiment of the specification is not limited thereto. For example, the first light emitting element LE1 may emit the first light, the second light emitting element LE2 and the fourth light emitting element LE4 may emit the third light, and the third light emitting element LE3 may emit the second light. As another example, the first light emitting element LE1 may emit the second light, the second light emitting element LE2 and the fourth light emitting element LE4 may emit the first light, and the third light emitting element LE3 may emit the third light. As another example, the first light emitting element LE1 may emit the first light, the second light emitting element LE2 may emit the second light, the third light emitting element LE3 may emit the third light, and the fourth light emitting element LE4 may emit the fourth light. The fourth light may be light in a yellow wavelength band. For example, the main peak wavelength of the fourth light may be positioned in approximately 550 nm to approximately 600 nm, but the embodiment of the specification is not limited thereto.

In addition, the first light emitting element LE1, the second light emitting element LE2, the third light emitting element LE3, and the fourth light emitting element LE4 may have a circular planar shape, but the embodiment of the specification is not limited thereto. For example, the first light emitting element LE1, the second light emitting element LE2, the third light emitting element LE3, and the fourth light emitting element LE4 may have a polygonal shape such as a triangle shape, a quadrilateral shape, a pentagonal shape, a hexagonal shape, and an octagonal shape, an elliptical shape, or an irregular shape.

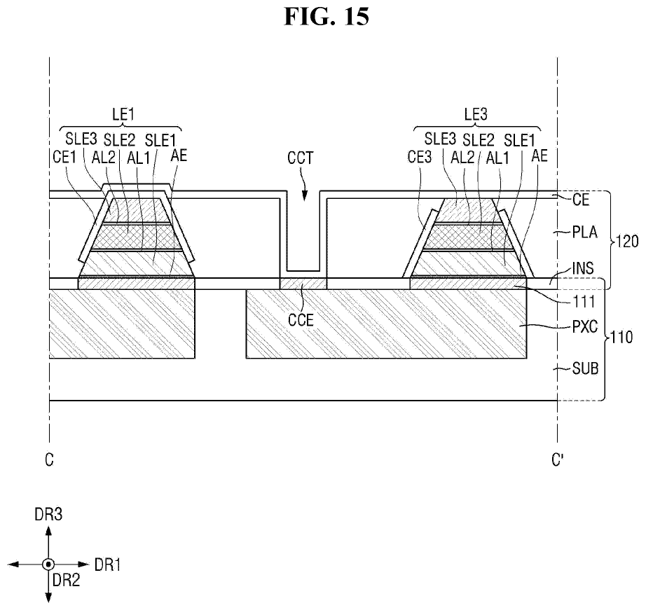

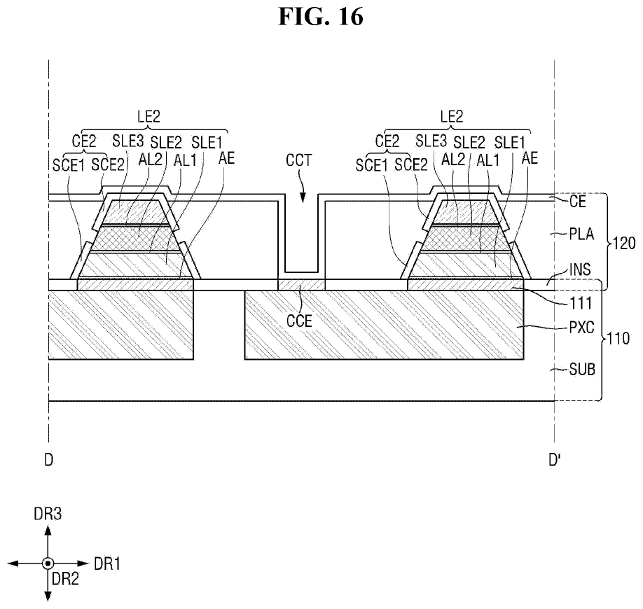

FIG. 15 is a schematic cross-sectional view illustrating an example of a display panel taken along line C-C′ of FIG. 14. FIG. 16 is a schematic cross-sectional view illustrating an example of a display panel taken along line D-D′ of FIG. 14.

The embodiment of FIGS. 15 and 16 differs from the embodiment of FIG. 5 at least in that the common electrode CE is electrically connected to a common connection electrode CCE through the common connection portion CCT. Repetitive descriptions of the parts already described in the embodiment of FIG. 5 will be omitted from those of FIGS. 15 and 16.

Referring to FIGS. 15 and 16, each of the common connection electrodes CCE may be disposed on the corresponding pixel circuit part PXC. Each of the common connection electrodes CCE may be an exposed electrode exposed from the pixel circuit part PXC. For example, each of the common connection electrodes CCE may protrude from the top surface of the pixel circuit part PXC. Each of the common connection electrodes CCE may be integral with the pixel circuit part PXC. Each of the common connection electrodes CCE may be supplied with a common voltage from the pixel circuit part PXC. Each of the common connection electrodes CCE may be integral with the pixel circuit part PXC. The side surface of each of the common connection electrodes CCE may contact the insulating layer INS. The top surfaces of the common connection electrodes CCE and the top surface of the insulating layer INS may be flat. In addition, the top surfaces of the pixel electrodes 111 and the top surface of the insulating layer INS may be flat.

The common connection electrodes CCE and the pixel electrodes 111 may be disposed on a same layer and may include a same material. The common connection electrodes CCE may include aluminum (Al).

At least a portion of each of the common connection electrodes CCE may be exposed by the common connection portion CCT penetrating the planarization layer PLA without being covered by the planarization layer PLA. Accordingly, each of the common connection electrodes CCE may be electrically connected to the common electrode CE through the common connection portion CCT. Accordingly, the common voltage from the pixel circuit part PXC may be supplied to the common electrode CE through the common connection electrode CCE.

Since the fourth light emitting element LE4 may be substantially the same as the second light emitting element LE2, a description of the fourth light emitting element LE4 will be omitted.

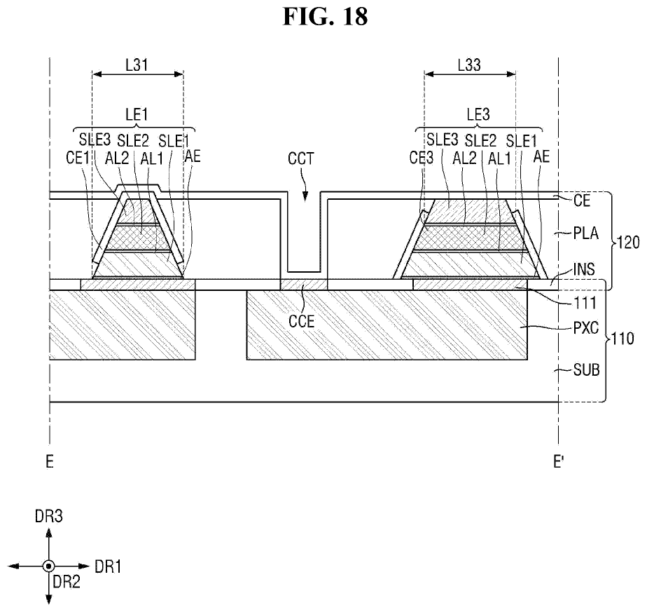

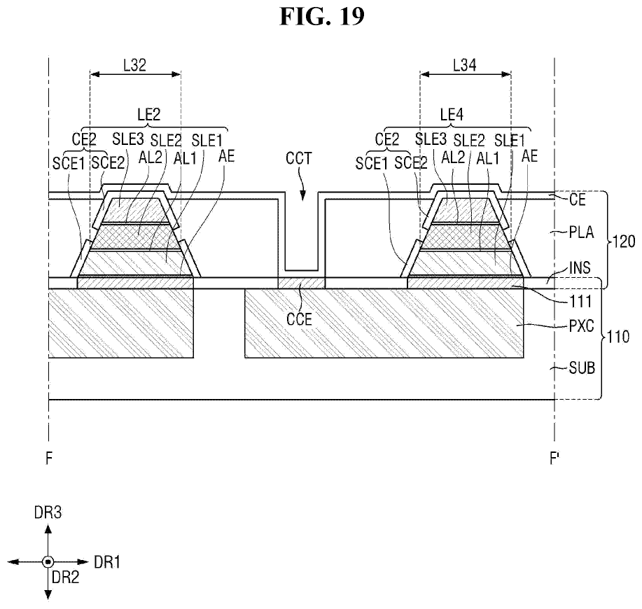

FIG. 17 is a schematic layout view illustrating pixels of a display panel according to still another embodiment. FIG. 18 is a schematic cross-sectional view illustrating an example of a display panel taken along line E-E′ of FIG. 17. FIG. 19 is a schematic cross-sectional view illustrating an example of a display panel taken along line F-F′ of FIG. 17.

The embodiment of FIGS. 17 to 19 differs from the embodiment of FIGS. 14 to 16 in that the size of the first light emitting element LE1, the size of the second light emitting element LE2 or the fourth light emitting element LE4, and the size of the third light emitting element LE3 are different. Repetitive descriptions of the parts already described in the embodiment of FIGS. 14 to 16 will be omitted from those of FIGS. 17 to 19.

Referring to FIGS. 17 to 19, the area of the top surface of each of the first light emitting elements LE1, the second light emitting elements LE2, the third light emitting elements LE3, and the fourth light emitting elements LE4 may be smaller than the area of the bottom surface thereof. Each of the first light emitting elements LE1, the second light emitting elements LE2, the third light emitting elements LE3, and the fourth light emitting elements LE4 may have a shape of a truncated cone in which an area of a top surface is smaller than an area of a bottom surface. In this case, a cross section of each of the first light emitting elements LE1, the second light emitting elements LE2, the third light emitting elements LE3, and the fourth light emitting elements LE4 may have a trapezoidal shape.

Accordingly, in case that the light emission efficiency of the first sub light emitting element SLE1, the light emission efficiency of the second sub light emitting element SLE2, the light emission efficiency of the third sub light emitting element SLE3, and the light emission efficiency of the second sub light emitting element SLE2 are similar, the area of the first sub light emitting element SLE1 emitting the first light in the first light emitting element LE1, the area of the second sub light emitting element SLE2 emitting the second light in the second light emitting element LE2, the area of the third sub light emitting element SLE3 emitting the third light in the third light emitting element LE3, and the area of the second sub light emitting element SLE2 emitting the second light in the fourth light emitting element LE4 may be substantially the same.

A maximum length L31 in the first direction DR1 of the first sub light emitting element SLE1 of the first light emitting element LE1, a maximum length L32 in the first direction DR1 of the second sub light emitting element SLE2 of the second light emitting element LE2, a maximum length L33 in the first direction DR1 of the third sub light emitting element SLE3 of the third light emitting element LE3, and a maximum length L34 in the first direction DR1 of the second sub light emitting element SLE2 of the fourth light emitting element LE4 may be substantially the same. In addition, the maximum length in the second direction DR2 of the first sub light emitting element SLE1 of the first light emitting element LE1, the maximum length in the second direction DR2 of the second sub light emitting element SLE2 of the second light emitting element LE2, the maximum length in the second direction DR2 of the third sub light emitting element SLE3 of the third light emitting element LE3, and the maximum length in the second direction DR2 of the second sub light emitting element SLE2 of the fourth light emitting element LE4 may be substantially the same.

In case that each of the first light emitting elements LE1, the second light emitting elements LE2, and the third light emitting elements LE3 has a shape of a truncated cone in which an area of a top surface is smaller than an area of a bottom surface, and the second sub light emitting element SLE2 is disposed on the first sub light emitting element SLE1 and the third sub light emitting element SLE3 is disposed on the second sub light emitting element SLE2, in a case where the area of the first sub light emitting element SLE1 of the first light emitting element LE1, the area of the second sub light emitting element SLE2 of the second light emitting element LE2, the area of the third sub light emitting element SLE3 of the third light emitting element LE3, and the area of the second sub light emitting element SLE2 of the fourth light emitting element LE4 are the same, the size of the first light emitting element LE1 may be the smallest, and the size of the third light emitting element LE3 may be the largest. The size of the second light emitting element LE2 and the size of the fourth light emitting element LE4 may be substantially the same. Accordingly, the area of the top surface of the second light emitting element LE2 or the fourth light emitting element LE4 exposed without being covered by the planarization layer PLA may be larger than the area of the top surface of the first light emitting element LE1 exposed without being covered with the planarization layer PLA. The area of the top surface of the third light emitting element LE3 exposed without being covered by the planarization layer PLA may be larger than the area of the top surface of the second light emitting element LE2 or the fourth light emitting element LE4 exposed without being covered by the planarization layer PLA.

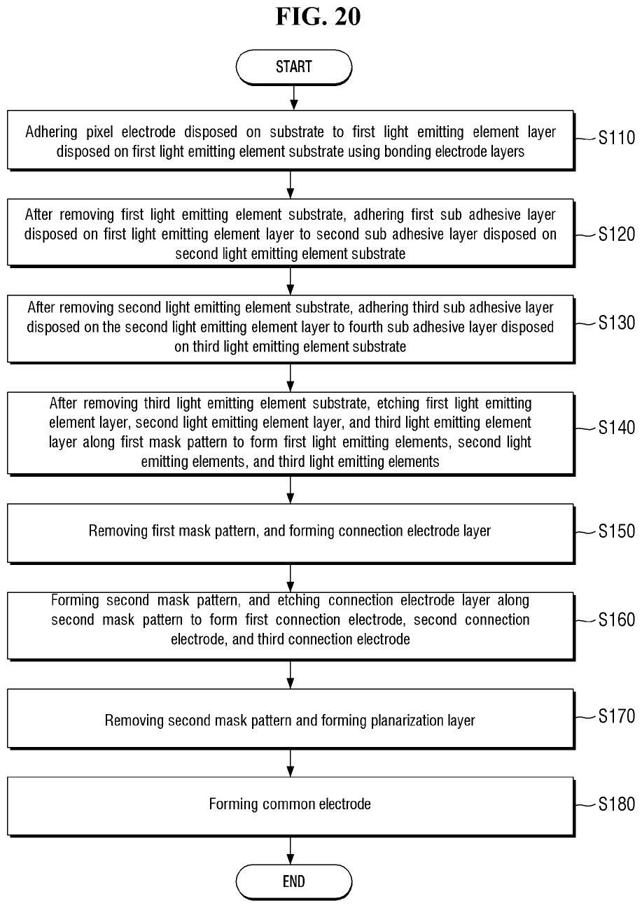

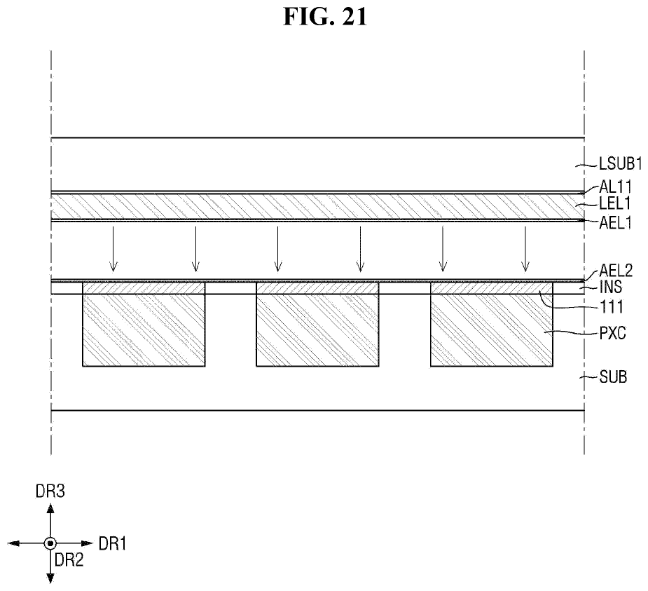

FIG. 20 is a schematic flowchart illustrating a method for fabricating a display panel according to an embodiment. FIGS. 21 to 28 are schematic cross-sectional views illustrating a method for fabricating a display panel according to an embodiment. Each of FIGS. 21 to 28 illustrates a cross section of a display panel taken along line A-A′ of FIG. 2.

Firstly, as illustrated in FIG. 21, the pixel electrode 111 disposed on the substrate SUB and a first light emitting element layer LEL1 disposed on a first light emitting element substrate LSUB1 are adhered using bonding electrode layers AEL1 and AEL2 (step S110 in FIG. 20).

The first light emitting element substrate LSUB1 may be a silicon substrate or a sapphire substrate. A first sub adhesive layer AL11 may be disposed on the first light emitting element substrate LSUB1, the first light emitting element layer LEL1 may be disposed on the first sub adhesive layer AL11, and the first bonding electrode layer AEL1 may be disposed on the first light emitting element layer LEL1. The first light emitting element layer LEL1 may include the first p-type semiconductor layer PSEM1, the first active layer MQW1, and the first n-type semiconductor layer NSEM1 illustrated in FIG. 6. In this case, the first n-type semiconductor layer NSEM1 may be disposed on the first sub adhesive layer AL11, the first active layer MQW1 may be disposed on the first n-type semiconductor layer NSEM1, the first p-type semiconductor layer PSEM1 may be disposed on the first active layer MQW1, and the first bonding electrode layer AEL1 may be disposed on the first p-type semiconductor layer PSEM1.

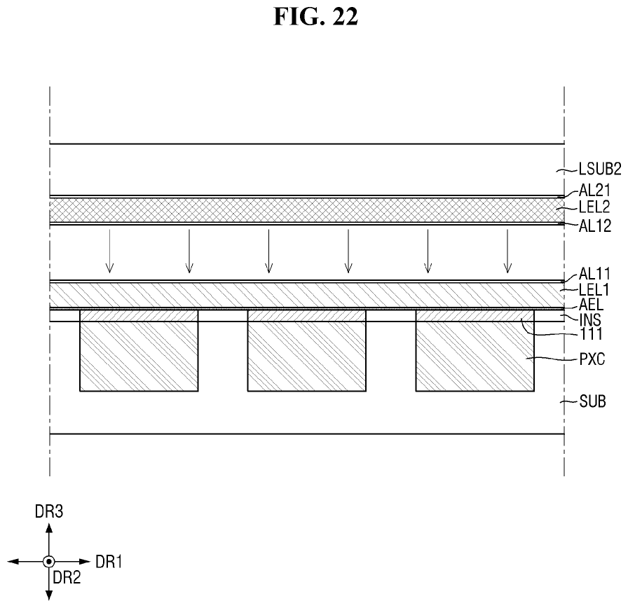

The second bonding electrode layer AEL2 disposed on the pixel electrode 111 and the insulating layer INS may face the first bonding electrode layer AEL1 disposed on the first light emitting element substrate LSUB1. After the first bonding electrode layer AEL1 and the second bonding electrode layer AEL2 are brought into contact with each other, by the melt-bonding at a temperature (e.g., a predetermined or selected temperature), a bonding electrode layer AEL of FIG. 22 may be formed. The bonding electrode layer AEL of FIG. 22 may include at least one of gold (Au), copper (Cu), aluminum (Al), or tin (Sn). As another example, the bonding electrode layer AEL of FIG. 22 may include a first layer including any one of gold (Au), copper (Cu), aluminum (Al), and tin (Sn) and a second layer including another one of gold (Au), copper (Cu), aluminum (Al), and tin (Sn). As another example, the bonding electrode layer AEL of FIG. 22 may include a transparent conductive oxide such as indium tin oxide (ITO) or indium zinc oxide (IZO).

Secondly, as illustrated in FIG. 22, after the first light emitting element substrate LSUB1 is removed, the first sub adhesive layer AL11 disposed on the first light emitting element layer LEL1 and a second sub adhesive layer AL12 disposed on a second light emitting element substrate LSUB2 are adhered (step 5120 in FIG. 20).

The first light emitting element substrate LSUB1 may be separated from the first light emitting element layer LEL1 by a laser lift-off process. As another example, the first light emitting element substrate LSUB1 may be removed by a polishing process such as a chemical mechanical polishing (CMP) process and/or an etching process.

The second light emitting element substrate LSUB2 may be a silicon substrate or a sapphire substrate. A third sub adhesive layer AL21 may be disposed on the second light emitting element substrate LSUB2, a second light emitting element layer LEL2 may be disposed on the third sub adhesive layer AL21, and the second sub adhesive layer AL12 may be disposed on the second light emitting element layer LEL2. The second light emitting element layer LEL2 may include the second p-type semiconductor layer PSEM2, the second active layer MQW2, and the second n-type semiconductor layer NSEM2 illustrated in FIG. 7. In this case, the second n-type semiconductor layer NSEM2 may be disposed on the third sub adhesive layer AL21, the second active layer MQW2 may be disposed on the second n-type semiconductor layer NSEM2, the second p-type semiconductor layer PSEM2 may be disposed on the second active layer MQW2, and a first adhesive layer AL1 may be disposed on the second p-type semiconductor layer PSEM2.

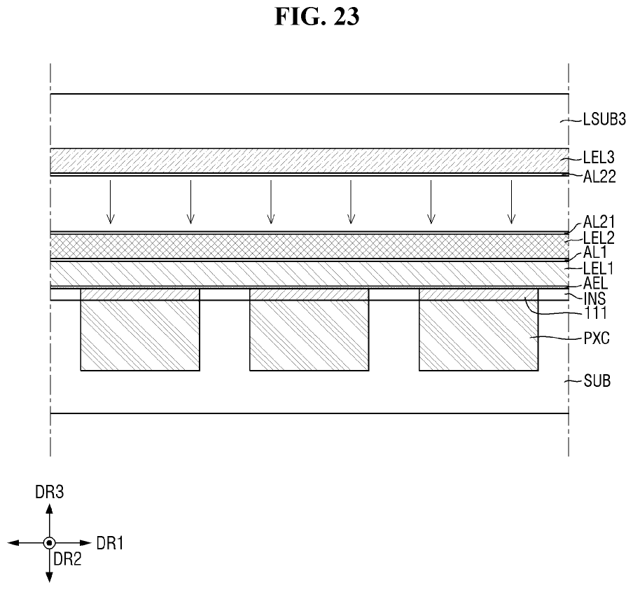

The first sub adhesive layer AL11 disposed on the first light emitting element layer LEL1 may face the second sub adhesive layer AL12 disposed on the second light emitting element substrate LSUB2. After the first sub adhesive layer AL11 and the second sub adhesive layer AL12 are brought into contact with each other, by the melt-bonding at a temperature (e.g., a predetermined or selected temperature), the first adhesive layer AL1 of FIG. 23 may be formed. The first adhesive layer AL1 of FIG. 23 may include a transparent conductive oxide such as indium tin oxide (ITO) or indium zinc oxide (IZO). In this case, the thickness of the first adhesive layer AL1 in FIG. 23 may be approximately 15 nm, but the embodiment of the specification is not limited thereto. As another example, the first adhesive layer AL1 may be a cured transparent adhesive resin or a cured transparent adhesive film.

Thirdly, as illustrated in FIG. 23, after the second light emitting element substrate LSUB2 is removed, the third sub adhesive layer AL21 disposed on the second light emitting element layer LEL2 and a fourth sub adhesive layer AL22 disposed on a third light emitting element substrate LSUB3 are adhered (step 5130 in FIG. 20).

The second light emitting element substrate LSUB2 may be separated from the second light emitting element layer LEL2 by a laser lift-off process. As another example, the second light emitting element substrate LSUB2 may be removed by a polishing process such as a chemical mechanical polishing (CMP) process and/or an etching process.

The third light emitting element substrate LSUB3 may be a silicon substrate or a sapphire substrate. A third light emitting element layer LEL3 may be disposed on the third light emitting element substrate LSUB3, and a fourth sub adhesive layer AL22 may be disposed on the third light emitting element layer LEL3. The third light emitting element layer LEL3 may include a third p-type semiconductor layer PSEM3, a third active layer MQW3, and a third n-type semiconductor layer NSEM3 illustrated in FIG. 8. In this case, the third n-type semiconductor layer NSEM3 may be disposed on the third light emitting element substrate LSUB3, the third active layer MQW3 may be disposed on the third n-type semiconductor layer NSEM3, the third p-type semiconductor layer PSEM3 may be disposed on the third active layer MQW3, and the fourth sub adhesive layer AL22 may be disposed on the third p-type semiconductor layer PSEM3.

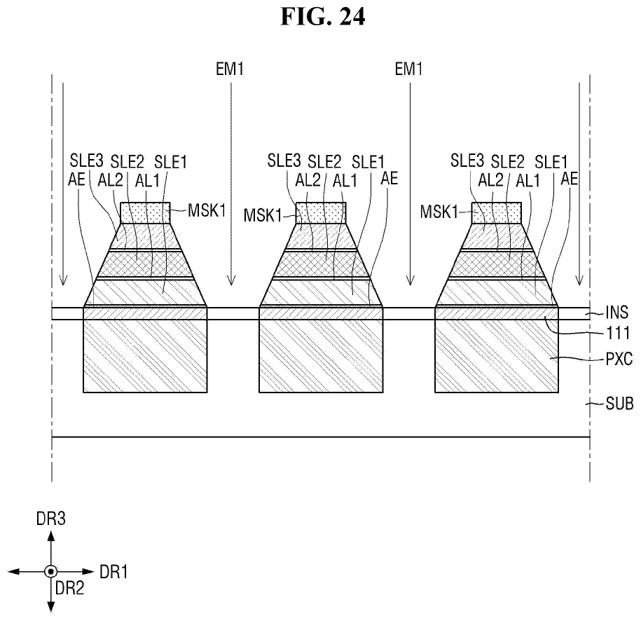

The third sub adhesive layer AL21 disposed on the second light emitting element layer LEL2 may face the fourth sub adhesive layer AL21 disposed on the third light emitting element substrate LSUB3. After the third sub adhesive layer AL21 and the fourth sub adhesive layer AL22 are brought into contact with each other, a second adhesive layer AL2 of FIG. 24 may be formed by the melt-bonding at a temperature. The second adhesive layer AL2 of FIG. 24 may include a transparent conductive oxide such as indium tin oxide (ITO) or indium zinc oxide (IZO). In this case, the thickness of the second adhesive layer AL2 in FIG. 24 may be approximately 15 nm, but the embodiment of the specification is not limited thereto. As another example, the second adhesive layer AL2 in FIG. 24 may be a cured transparent adhesive resin or a cured transparent adhesive film.

Fourthly, as illustrated in FIG. 24, after removing the third light emitting element substrate LSUB3, the first light emitting element layer LEL1, the second light emitting element layer LEL2, and the third light emitting element layer LEL3 are etched according to a first mask pattern MSK1 to form the first light emitting elements LE1, the second light emitting elements LE2, and the third light emitting elements LE3 (step S140 in FIG. 20).

The third light emitting element substrate LSUB3 may be separated from the third light emitting element layer LEL3 by a laser lift-off process. As another example, the third light emitting element substrate LSUB3 may be removed by a polishing process such as a chemical mechanical polishing (CMP) process and/or an etching process.

The first mask pattern MSK1 is formed on the third light emitting element layer LEL3. The first light emitting element layer LEL1, the second light emitting element layer LEL2, and the third light emitting element layer LEL3 may be etched using a first etching material EM1 with the first mask pattern MSK1 as a mask. Accordingly, the first light emitting elements LE1, the second light emitting elements LE2, and the third light emitting elements LE3 apart from each other may be formed.

Each of the first light emitting elements LE1, the second light emitting elements LE2, and the third light emitting elements LE3 may have a shape of a truncated cone in which an area of a top surface is smaller than an area of a bottom surface. In this case, each of the first light emitting elements LE1, the second light emitting elements LE2, and the third light emitting elements LE3 may have a trapezoidal cross-sectional shape.

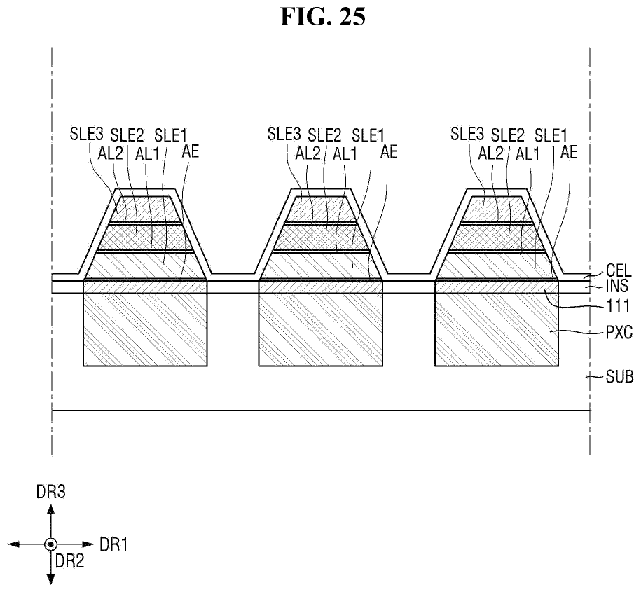

Fifthly, as illustrated in FIG. 25, the first mask pattern MSK1 is removed, and a connection electrode layer CEL is formed (step S150 in FIG. 20).

The connection electrode layer CEL may be disposed on the top surface and side surface of each of the first light emitting elements LE1, the second light emitting elements LE2, and the third light emitting elements LE3. The connection electrode layer CEL may be disposed on the insulating layer INS disposed between the light emitting elements LE1, LE2, and LE3. The connection electrode layer CEL may include a transparent conductive oxide such as indium tin oxide (ITO) or indium zinc oxide (IZO).

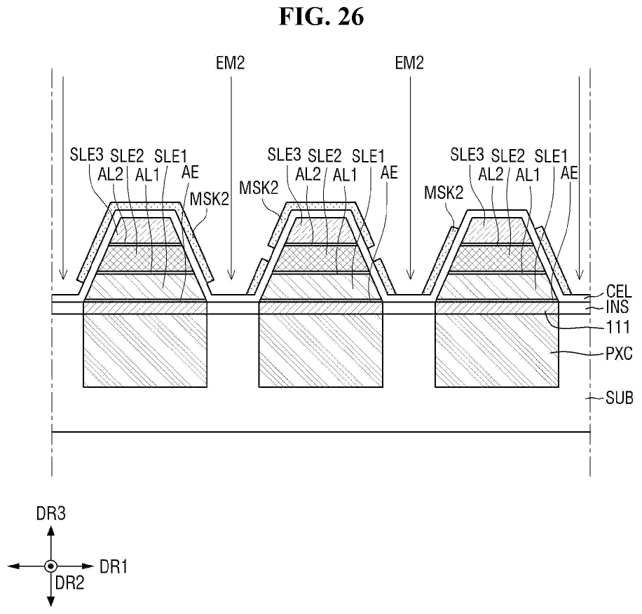

Sixthly, as illustrated in FIG. 26, a second mask pattern MSK2 is formed, and the connection electrode layer CEL is etched according to the second mask pattern MSK2 to form the first connection electrode CE1, the second connection electrode CE2, and the third connection electrode CE3 (step S160 in FIG. 20).

The second mask pattern MSK2 is formed on the connection electrode layer CEL. The connection electrode layer CEL may be etched using a second etching material EM2 with the second mask pattern MSK2 as a mask. Accordingly, the first connection electrode CE1, the second connection electrode CE2, and the third connection electrode CE3 apart from each other may be formed.

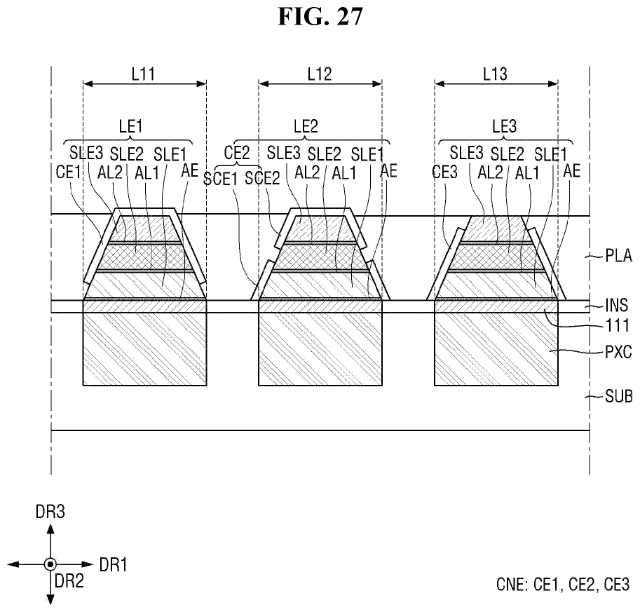

Seventhly, as illustrated in FIG. 27, after the second mask pattern MSK2 is removed, the planarization layer PLA is formed (step S170 in FIG. 20).

The planarization layer PLA may fill a space between the light emitting elements LE1, LE2, and LE3 to planarize a step caused by the light emitting elements LE1, LE2, and LE3. The planarization layer PLA may cover the side surface of each of the first light emitting elements LE1, the side surface of each of the second light emitting elements LE2, and the side surface of each of the third light emitting elements LE3. The planarization layer PLA does not cover the top surface of each of the first light emitting elements LE1, the top surface of each of the second light emitting elements LE2, and the top surface of each of the third light emitting elements LE3. For example, the planarization layer PLA does not cover the top surface of the first connection electrode CE1 of each of the first light emitting elements LE1 and the top surface of the second connection electrode CE2 of each of the second light emitting elements LE2. In addition, the planarization layer PLA does not cover the top surface of each of the third light emitting elements LE3.

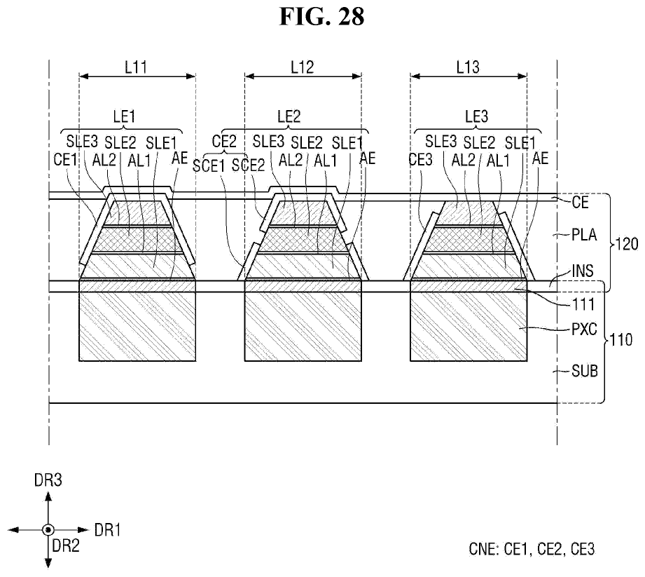

Eighthly, as illustrated in FIG. 28, the common electrode CE is formed on the top surface of each of the first light emitting elements LE1, the top surface of each of the second light emitting elements LE2, the top surface of each of the third light emitting elements LE3, and the top surface of the planarization layer PLA (step S180 in FIG. 20).

The common electrode CE may contact the first connection electrode CE1 of each of the first light emitting elements LE1, the second sub connection electrode SCE2 of the second connection electrode CE2 of each of the second light emitting elements LE2, and the top surface of the third light emitting element LE3. The common electrode CE may include a transparent conductive material. The common electrode CE may be formed of a transparent conductive oxide such as indium tin oxide (ITO) or indium zinc oxide (IZO). The thickness of the common electrode CE may be approximately 100 nm, but the embodiment of the specification is not limited thereto.

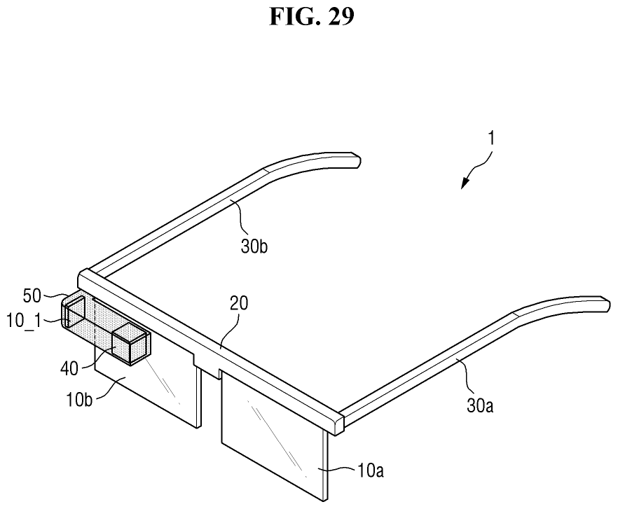

FIG. 29 is a schematic diagram illustrating an example virtual reality device including a display device according to an embodiment. FIG. 29 illustrates a virtual reality device 1 to which a display device 10_1 according to an embodiment is applied.

Referring to FIG. 29, the virtual reality device 1 according to an embodiment may be a glass-type device. The virtual reality device 1 according to an embodiment may include the display device 10_1, a left lens 10a, a right lens 10b, a support frame 20, temples 30a and 30b, a reflection member 40, and a display device storage 50.

Although FIG. 29 illustrates the virtual reality device 1 including the temples 30a and 30b, the virtual reality device 1 according to an embodiment may be applied to a head-mounted display including a head-mounted band that may be worn on a head, instead of the temples 30a and 30b. For example, the virtual reality device 1 according to an embodiment is not limited to that shown in FIG. 29, and may be applied in various forms to various electronic devices.

The display device storage 50 may include the display device 10_1 and the reflection member 40. The image displayed on the display device 10_1 may be reflected by the reflection member 40 and provided to a user's right eye through the right lens 10b. Accordingly, the user can view the virtual reality image displayed on the display device 10_1 through the right eye.

FIG. 29 illustrates that the display device storage 50 is disposed at the end on the right side of the support frame 20, but the embodiment of the specification is not limited thereto. For example, the display device storage 50 may be disposed at the left end of the support frame 20, and in this case, the image displayed on the display device 10_1 may be reflected by the reflection member 40 and provided to a user's left eye through the left lens 10a. Accordingly, the user can view the virtual reality image displayed on the display device 10_1 through the left eye. As another example, the display device storage 50 may be disposed at both the left end and the right end of the support frame 20. In that case, the user can view the virtual reality image displayed on the display device 10_1 through both the left eye and the right eye.

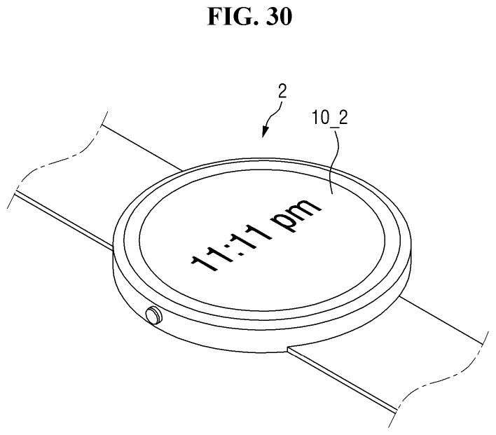

FIG. 30 is a schematic diagram illustrating a smart device including a display device according to an embodiment.

Referring to FIG. 30, a display device 10_2 according to an embodiment may be applied to a smart watch 2 that is one of the smart devices.

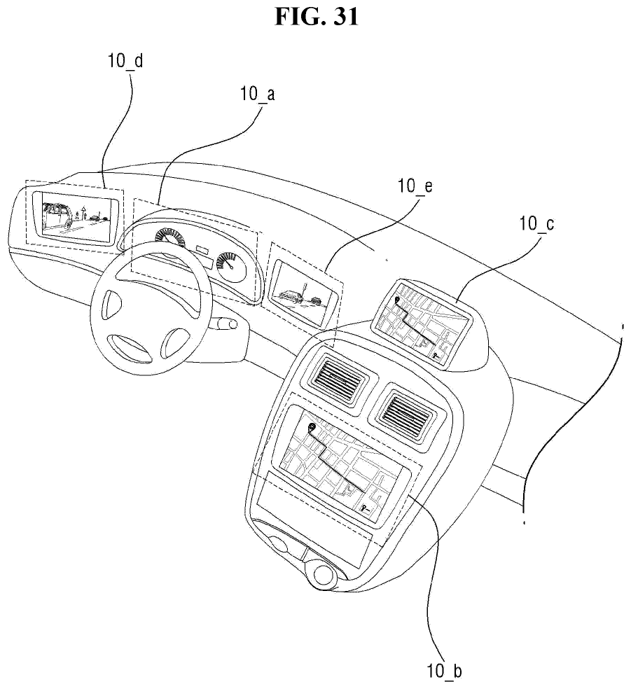

FIG. 31 is a schematic diagram illustrating an example vehicle instrument panel (or dashboard) and a center fascia including a display device according to an embodiment. FIG. 31 illustrates a vehicle to which display devices 10_a, 10_b, 10_c, 10_d, and 10_e according to an embodiment are applied.

Referring to FIG. 31, the display devices 10_a, 10_b, and 10_c according to an embodiment may be applied to the dashboard of an automobile, the center fascia of the automobile, or the center information display (CID) of the dashboard of the automobile. Further, the display devices 10_d and 10_e according to an embodiment may be applied to a room mirror display instead of side-view mirrors of the automobile.

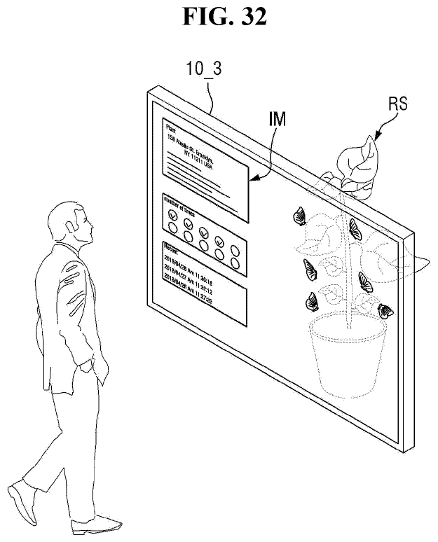

FIG. 32 is a schematic diagram illustrating a transparent display device including a display device according to an embodiment.

Referring to FIG. 32, a display device 10_3 according to an embodiment may be applied to the transparent display device. The transparent display device may display an image IM and also may transmit light. Thus, a user located on the front side of the transparent display device can view an object RS or a background on the rear side of the transparent display device as well as the image IM displayed on the display device 10_3. In case that the display device 10_3 is applied to a transparent display device, the substrate SUB illustrated in FIG. 5 may include a light transmission portion capable of transmitting light or may be formed of a material capable of transmitting light.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel electrode disposed on a substrate;
a light emitting element disposed on the pixel electrode;
a connection electrode disposed on a side surface of the light emitting element; and
a common electrode disposed on the light emitting element, wherein
the light emitting element includes:
a first sub light emitting element;
a second sub light emitting element disposed on the first sub light emitting element; and
a third sub light emitting element disposed on the second sub light emitting element,
the connection electrode is disposed on at least one side surface of the first sub light emitting element, the second sub light emitting element, and the third sub light emitting element.

2. The display device of claim 1, wherein each of the first sub light emitting element, the second sub light emitting element, and the third sub light emitting element includes a first semiconductor layer, an active layer, and a second semiconductor layer sequentially stacked.

3. The display device of claim 2, wherein the connection electrode is disposed on a side surface of the second semiconductor layer of the first sub light emitting element, a side surface of the first semiconductor layer, a side surface of the active layer, and a side surface of the second semiconductor layer of the second sub light emitting element, and a side surface of the first semiconductor layer, a side surface of the active layer, and a side surface of the second semiconductor layer of the third sub light emitting element.

4. The display device of claim 3, wherein the connection electrode is electrically connected to the common electrode.

5. The display device of claim 3, wherein the first sub light emitting element emits light of a first color wavelength band.

6. The display device of claim 2, wherein the connection electrode includes:
a first sub connection electrode disposed on a side surface of the first semiconductor layer, a side surface of the active layer, and a side surface of the second semiconductor layer of the first sub light emitting element, and a side surface of the first semiconductor layer of the second sub light emitting element; and
a second sub connection electrode disposed on a side surface of the active layer of the second sub light emitting element and a side surface of the first semiconductor layer, a side surface of the active layer, and a side surface of the second semiconductor layer of the third sub light emitting element.

7. The display device of claim 6, wherein the second sub connection electrode is electrically connected to the common electrode.

8. The display device of claim 6, wherein the second sub light emitting element emits light of a second color wavelength band.

9. The display device of claim 2, wherein the connection electrode is disposed on a side surface of the first semiconductor layer, a side surface of the active layer, and a side surface of the second semiconductor layer of the first sub light emitting element, and a side surface of the first semiconductor layer, a side surface of the active layer, and a side surface of the second semiconductor layer of the second sub light emitting element, and a side surface of the first semiconductor layer of the third sub light emitting element.

10. The display device of claim 9, wherein the connection electrode is spaced apart from the common electrode.

11. The display device of claim 9, wherein the third sub light emitting element emits light of a third color wavelength band.

12. The display device of claim 1, further comprising:
a first adhesive layer disposed between the first sub light emitting element and the second sub light emitting element; and
a second adhesive layer disposed between the second sub light emitting element and the third sub light emitting element.

13. The display device of claim 12, wherein each of a thickness of the first adhesive layer and a thickness of the second adhesive layer is smaller than a thickness of the connection electrode.

14. The display device of claim 12, wherein the first adhesive layer, the second adhesive layer, and the connection electrode include a same material.

15. A display device comprising:
a first pixel electrode and a second pixel electrode disposed on a substrate and spaced apart from each other;
a first light emitting element disposed on the first pixel electrode;
a second light emitting element disposed on the second pixel electrode;
a first connection electrode disposed on at least a portion of a side surface of the first light emitting element;
a second connection electrode disposed on at least a portion of a side surface of the second light emitting element; and
a common electrode disposed on the first light emitting element and the second light emitting element,
wherein the common electrode is electrically connected to at least one of the first connection electrode and the second connection electrode.

16. The display device of claim 15, further comprising:
a third pixel electrode disposed on the substrate and spaced apart from the first pixel electrode and the second pixel electrode;
a third light emitting element disposed on the third pixel electrode; and
a third connection electrode disposed on at least a portion of a side surface of the third light emitting element,
wherein the common electrode is electrically connected to at least two of the first connection electrode, the second connection electrode, and the third connection electrode.

17. The display device of claim 16, wherein
each of the first light emitting element, the second light emitting element, and the third light emitting element includes:
a first sub light emitting element;
a second sub light emitting element disposed on the first sub light emitting element; and
a third sub light emitting element disposed on the second sub light emitting element,
each of the first sub light emitting element, the second sub light emitting element, and the third sub light emitting element includes a first semiconductor layer, an active layer, and a second semiconductor layer sequentially stacked.

18. The display device of claim 17, wherein the first connection electrode is electrically connected to the second semiconductor layer of the first sub light emitting element, the first semiconductor layer, the active layer, and the second semiconductor layer of the second sub light emitting element, and the first semiconductor layer, the active layer, and the second semiconductor layer of the third sub light emitting element of the first light emitting element.

19. The display device of claim 17, wherein the second connection electrode includes:
a first sub connection electrode electrically connected to the first semiconductor layer, the active layer, and the second semiconductor layer of the first sub light emitting element and the first semiconductor layer of the second sub light emitting element of the second light emitting element; and
a second sub connection electrode electrically connected to the second semiconductor layer of the second sub light emitting element, and the first semiconductor layer, the active layer, and the second semiconductor layer of the third sub light emitting element of the second light emitting element.

20. The display device of claim 17, wherein the third connection electrode is electrically connected to the first semiconductor layer, the active layer, and the second semiconductor layer of the first sub light emitting element, the first semiconductor layer, the active layer, and the second semiconductor layer of the second sub light emitting element, and the first semiconductor layer of the third sub light emitting element of the third light emitting element.

21. A method for fabricating a display device, comprising:
adhering a pixel electrode disposed on a substrate to a first light emitting element layer disposed on a first light emitting element substrate by bonding electrode layers;
adhering a first sub adhesive layer disposed on the first light emitting element layer to a second sub adhesive layer disposed on the second light emitting element layer;
adhering a third sub adhesive layer disposed on the second light emitting element layer to a fourth sub adhesive layer disposed on the third light emitting element layer;
forming a first mask pattern on the third light emitting element layer, and etching the first light emitting element layer, the second light emitting element layer, and the third light emitting element layer exposed without being covered by the first mask pattern to form first light emitting elements, second light emitting elements, and third light emitting elements;
removing the first mask pattern, and forming a connection electrode layer on the first light emitting elements, the second light emitting elements, and the third light emitting elements; and
forming a second mask pattern on the connection electrode layer, and etching the connection electrode layer exposed without being covered by the second mask pattern to form a first connection electrode, a second connection electrode, and a third connection electrode.
